(19) United States
(12) Patent Application Publication
(10) Pub. No.: US 2024/0055368 A1
(43) Pub. Date: Feb. 15, 2024

(54) SEMICONDUCTOR DEVICES WITH PYRAMIDAL SHIELDING AND METHOD FOR MAKING THE SAME

(71) Applicant: STATS ChipPAC Pte. Ltd., Singapore (SG)

(72) Inventors: ChangOh KIM, Incheon (KR); JinHee JUNG, Incheon (KR); OMin KWON, Incheon (KR)

(21) Appl. No.: 18/447,315

(22) Filed: Aug. 10, 2023

(30) Foreign Application Priority Data
Aug. 12, 2022 (CN) 202210968489.6

(51) Int. Cl. H01L 23/552; H01L 23/31; H01L 21/56

(52) U.S. Cl. CPC H01L 23/552; H01L 23/3121; H01L 21/565

(57) ABSTRACT

A semiconductor device and a method for making the same are provided. The semiconductor device includes: a substrate; an electronic component mounted on the substrate; a first encapsulant disposed on the substrate and encapsulating the electronic component; and a first electromagnetic interference (EMI) shielding layer disposed on the first encapsulant, wherein the first EMI shielding layer includes a first plurality of shield protrusions each having one or more inclined sidewalls.

### TECHNICAL FIELD

The present application generally relates to semiconductor technology, and more particularly, to a semiconductor device with a pyramidal shielding and a method for making the same.

### BACKGROUND OF THE INVENTION

The semiconductor industry is constantly faced with complex integration challenges as consumers want their electronics to be smaller, faster and higher performance with more and more functionalities packed into a single device. One of the solutions is System-in-Package (SiP). SiP is a functional electronic system or sub-system that includes in a single package two or more heterogeneous semiconductor dice, such as a logic chip, a memory, integrated passive devices, radio frequency (RF) filters, sensors, heat sinks, or antennas. However, high speed digital and RF electronic devices included in the SiP may serve as a source of an electromagnetic wave, which may interrupt, obstruct, or otherwise degrade or limit the effective performance of circuits in the SiP.

Therefore, a need exists for reducing electromagnetic interference (EMI) in semiconductor devices.

### SUMMARY OF THE INVENTION

An objective of the present application is to provide a semiconductor device with reduced electromagnetic interference.

According to an aspect of embodiments of the present application, a semiconductor device is provided. The semiconductor device may include: a substrate; an electronic component mounted on the substrate; a first encapsulant disposed on the substrate and encapsulating the electronic component; and a first electromagnetic interference (EMI) shielding layer disposed on the first encapsulant, wherein the first EMI shielding layer includes a first plurality of shield protrusions each having one or more inclined sidewalls.

According to another aspect of embodiments of the present application, a method for making a semiconductor device is provided. The method may include: providing a package including: a substrate; and an electronic component mounted on the substrate; forming a first encapsulant on the substrate and encapsulating the electronic component; and forming a first electromagnetic interference (EMI) shielding layer on the first encapsulant, wherein the first EMI shielding layer including a first plurality of shield protrusions each having one or more inclined sidewalls.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a cross-sectional view of a conventional semiconductor device.

FIG. 2A is a cross-sectional view of a semiconductor device according an embodiment of the present application.

FIG. 2B, FIG. 2C and FIG. 2D are enlarged views of a portion of the semiconductor device shown in FIG. 2A.

FIG. 3A is a cross-sectional view of a semiconductor device according an embodiment of the present application.

FIG. 3B and FIG. 3C are enlarged views of a portion of the semiconductor device shown in FIG. 3A.

FIG. 4A is a cross-sectional view of a semiconductor device according an embodiment of the present application.

FIG. 4B and FIG. 4C are enlarged views of a portion of the semiconductor device shown in FIG. 4A.

FIGS. 5A-5D are cross-sectional views of different semiconductor devices according embodiments of the present application.

FIGS. 6A-6D are cross-sectional views of different semiconductor devices according embodiments of the present application.

FIGS. 7A-7D are cross-sectional views of different semiconductor devices according embodiments of the present application.

FIGS. 8A to 8E are cross-sectional views illustrating various steps of a method for making a semiconductor device according to an embodiment of the present application.

FIG. 9 is a cross-sectional view illustrating a step of a method for making a semiconductor device according to an embodiment of the present application.

FIGS. 10A to 10E are cross-sectional views illustrating various steps of a method for making a semiconductor device according to an embodiment of the present application.

FIG. 11 is a cross-sectional view illustrating a step of a method for making a semiconductor device according to an embodiment of the present application.

FIGS. 12A to 12E are cross-sectional views illustrating various steps of a method for making a semiconductor device according to an embodiment of the present application.

FIGS. 13A to 13G are cross-sectional views illustrating various steps of a method for making a semiconductor device according to an embodiment of the present application.

FIGS. 14A to 14G are cross-sectional views illustrating various steps of a method for making a semiconductor device according to an embodiment of the present application.

FIGS. 15A to 15G are cross-sectional views illustrating various steps of a method for making a semiconductor device according to an embodiment of the present application.

FIGS. 16A to 16G are cross-sectional views illustrating various steps of a method for making a semiconductor device according to an embodiment of the present application.

FIGS. 17A to 17G are cross-sectional views illustrating various steps of a method for making a semiconductor device according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

FIG. 1 illustrates a cross-sectional view of a semiconductor device 100, in which a conformal EMI shielding layer 140 is formed to prevent electromagnetic noises radiated by high-frequency devices in SiP. As shown in FIG. 1, the device 100 includes a substrate 110 and a plurality of electronic components 122, 124 and 126 mounted thereon. The plurality of electronic components 122, 124 and 126 may include high speed digital and RF electronic devices, which radiate electromagnetic noises. An encapsulant 130 is disposed on the substrate 110 and encapsulates the electronic components 122, 124 and 126. The EMI shielding layer 140 is formed on the encapsulant 130 and coupled to a reference node or potential (e.g., ground), so as to inhibit electromagnetic waves generated in the semiconductor device 100 from leaking to the outside, and also inhibit external electromagnetic waves from entering into the semiconductor device 100. Generally, the EMI shielding layer 140 should be of a thickness that is sufficient to achieve desired shielding performance. However, the thicker EMI shielding layer 140 may increase the cost and the size of the semiconductor device 100.

To address at least one of the above problems, in the embodiments of the present application, a semiconductor device with an EMI shielding layer is provided. Specifically, the EMI shielding layer includes a plurality of protrusions each having one or more inclined sidewalls. In some examples, the one or more inclined sidewalls may intersect with each other or with other sidewalls at respective ridges topmost of the sidewalls to form a sawtooth/wave shaped protrusion profile. In some embodiments, the ridges may be in parallel with each other, and in some other embodiments, the ridges may not in parallel with each other. In some other examples, the one or more inclined sidewalls may converge at a pointed tip to form a cone shaped or pyramid shaped protrusion, as will be elaborated below.

In the semiconductor device of the present application, undesired electromagnetic waves can be reflected multiple times between the inclined sidewalls and thus significantly prevented from passing through the shielding layer. That is, the electromagnetic noises can be trapped among the inclined sidewalls of the protrusions, thereby facilitating the absorption of the electromagnetic noises by the shielding layer. Moreover, the pointed tips of the protrusions can serve as lightning rods of the semiconductor device due to higher electron density at these pointed tips. The electromagnetic noises can be induced toward the pointed tips, and finally flow to the ground through the shielding layer. Therefore, the shielding performance of the EMI shielding layer can be increased without increasing the thickness of the EMI shielding layer in the semiconductor device of the present application.

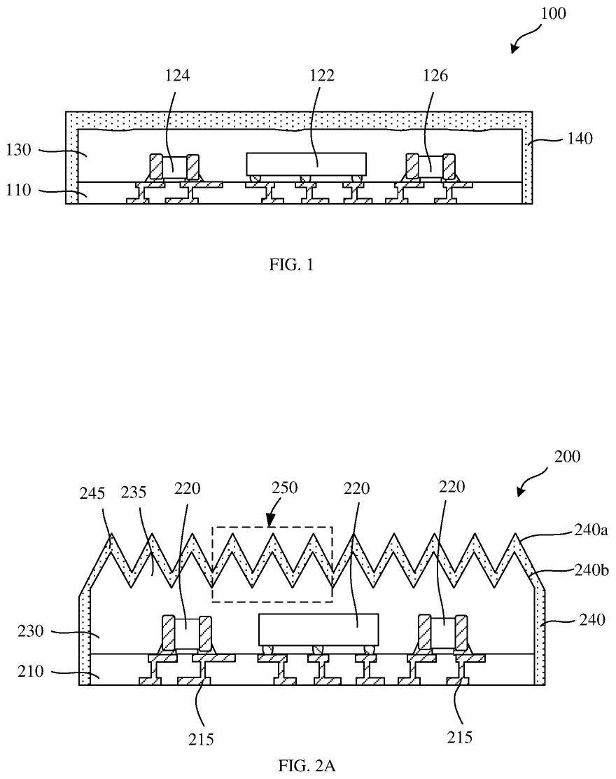

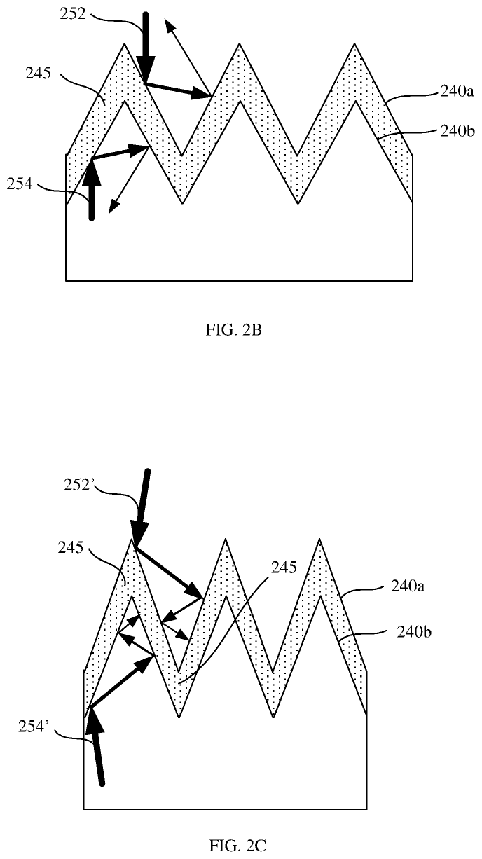

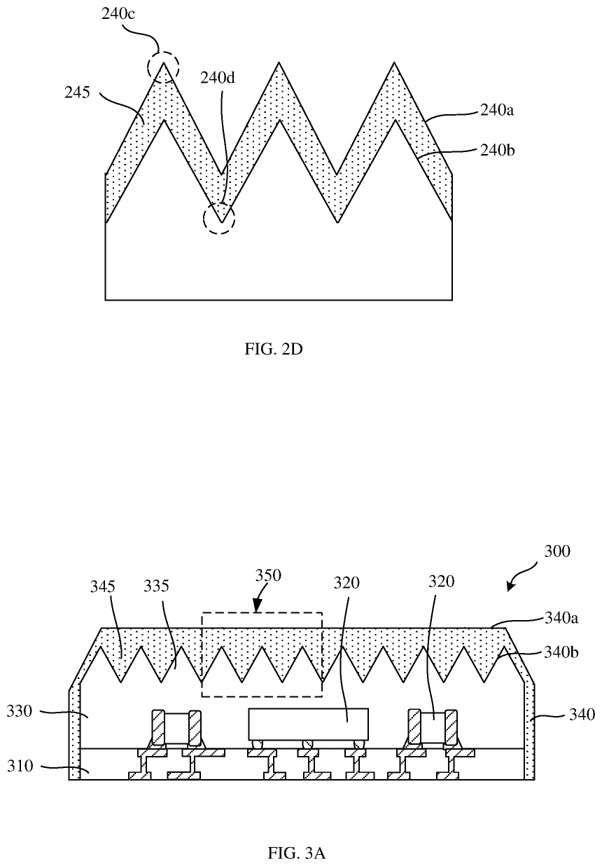

Referring now to FIG. 2A, a cross-sectional view of a semiconductor device 200 is illustrated according to an embodiment of the present application. As illustrated in FIG. 2A, the semiconductor device 200 includes a substrate 210, a plurality of electronic components 220, an encapsulant 230, and an EMI shielding layer 240.

The substrate 210 can support the plurality of electronic components 220 and further connect the plurality of electronic components 220 with each other or other electronic components. By way of example, the substrate 210 may include a printed wiring board or a semiconductor substrate, however, the substrate 210 is not to be limited to these examples. In other examples, the substrate 210 may be a laminate interposer, a strip interposer, a leadframe, or other suitable substrates. The substrate 210 may include any structure on or in which an integrated circuit system can be fabricated. For example, the substrate 210 may include one or more insulating or passivation layers, one or more conductive vias formed through the insulating layers, and one or more conductive layers formed over or between the insulating layers.

In the example shown in FIG. 2A, redistribution structures (RDS) 215 are formed in the substrate 210. The RDS may include one or more dielectric layers and one or more conductive layers between and through the dielectric layers. The conductive layers may define pads, traces and plugs through which electrical signals or voltages can be distributed horizontally and vertically across the RDS. As shown in the example of FIG. 2A, the RDS 215 may include a plurality of top conductive patterns formed on a top surface of the substrate 210 and a plurality of bottom conductive patterns formed on a bottom surface of the substrate 210. In addition, the RDS 215 may further include one or more conductive vias electrically connecting at least one of the top conductive patterns with at least one of the bottom conductive patterns. The RDS 215 may include one or more of Al, Cu, Sn, Ni, Au, Ag, or any other suitable electrically conductive materials. It could be understood that, the top conductive patterns, the bottom conductive patterns and the conductive vias may be implemented in various structures and types, but aspects of the present application are not limited thereto.

The plurality of electronic components 220 are mounted on the top surface of the substrate 210. The electronic components 220 may include any of a variety of types of semiconductor dice, semiconductor packages, or discrete devices. For example, the electronic components 220 may include a digital signal processor (DSP), a microcontroller, a microprocessor, a network processor, a power management processor, an audio processor, a video processor, an RF circuit, a wireless baseband system-on-chip (SoC) processor, a sensor, a memory controller, a memory device, an application specific integrated circuit, etc. The electronic components 220 may also include one or more passive electrical components such as resistors, capacitors, inductors, etc. In the example shown in FIG. 2A, the electronic components 220 includes one semiconductor die and two passive electrical components, but the scope of this application is not limited thereto. The electronic components 220 can be mounted on the top surface of the substrate 210 using any suitable surface mounting techniques.

In some embodiments, the electronic components 220 may contain devices or circuits that are susceptible to or can generate electromagnetic interference (EMI), radio frequency interference (RFI), harmonic distortion, and inter-device interference. In some examples, the electronic components 220 may include any component that is configured to provide several mobile functionalities and capabilities, including but not limited to, positioning functionality, wireless connectivity functionality (e.g., wireless communication) and/or cellular connectivity functionality (e.g., cellular communication). In some examples, the electronic components 220 may be configured to provide a radio frequency front end (RFFE) functionality. For example, the electronic components 220 may include, but not limited to, a power amplifier, a filter, a switch, a low noise amplifier (LNA), a tuner, a multiplexer, etc.

The encapsulant 230 may be disposed on the top surface of the substrate 210 and encapsulate the electronic components 220. The encapsulant 230 may be made of polymer composite material, such as epoxy resin with filler, epoxy acrylate with filler, or polymer with proper filler, but the scope of this application is not limited thereto. The encapsulant 230 is non-conductive, provides structural support, and environmentally protects the electronic components 220 from external elements and contaminants.

As shown in FIG. 2A, the encapsulant 230 includes a plurality of encapsulant protrusions 235 each having one or more inclined sidewalls converging at a pointed tip. In some embodiments, the plurality of encapsulant protrusions 235 may have a pyramidal shape. The pyramidal protrusion 235 may have a trilateral, quadrilateral or polygonal base, and a plurality of sidewalls. The plurality of sidewalls converges at the apex of the pyramidal protrusion 235. In some embodiments, the plurality of encapsulant protrusions 235 may have a conical shape. The conical protrusion may have a circular or elliptical base and a sidewall tapering smoothly from the base to the apex of conical protrusion. In some other embodiments, the one or more inclined sidewalls may intersect with each other or with other sidewalls at respective ridges to form a sawtooth/wave shaped protrusion profile. However, the scope of this application is not limited to the above shapes, and the plurality of encapsulants may have other regular or irregular shapes with one or more inclined sidewalls. In some embodiments, each encapsulant protrusions may have a triangular base and two non-inclined sidewall and an inclined sidewall, or have two or more inclined sidewalls. The inclined sidewall herein refers to a sidewall that is not perpendicular to the top or bottom surface of the substrate 210, or to another similar reference surface. In some embodiments, the inclined sidewall may have an angle relative to the reference surface (e.g., the top surface of the substrate) ranging from 30 degrees to 85 degrees.

The EMI shielding layer 240 is disposed on the encapsulant 230, and covers the top and lateral surfaces of the encapsulant 230 and the lateral surface of the substrate 210. The EMI shielding layer 240 may be coupled to a reference potential (e.g., ground), so as to inhibit electromagnetic waves generated in the semiconductor device 200 from leaking to the outside, and also inhibit external electromagnetic waves from entering into the semiconductor device 200. The EMI shielding layer 240 may be one or more layers of Al, Cu, Sn, Ni, Au, Ag, or other suitable conductive material. Alternatively, the EMI shielding layer 240 may be carbonyl iron, stainless steel, nickel silver, low-carbon steel, silicon-iron steel, foil, conductive resin, carbon-black, aluminum flake, or other metals and conductive materials capable of reducing the influence of EMI, RFI, and other inter-device interference.

As shown in FIG. 2A, the EMI shielding layer 240 has a bottom surface 240b conforming to the shape of the plurality of encapsulant protrusions 235 of the encapsulant 230, and a top surface 240a parallel to the bottom surface 240b. That is, the EMI shielding layer 240 conforms to the shape of the encapsulant protrusions 235 of the encapsulant 230, and also includes a plurality of shield protrusions 245 each having one or more inclined sidewalls converging at a pointed tip. For example, the shield protrusions 245 of the EMI shielding layer 240 may also have a pyramidal shape, a conical shape, etc.

FIG. 2B illustrates an enlarged view of a portion 250 of the semiconductor device 200 shown in FIG. 2A. In FIG. 2B, an electromagnetic wave 252 irradiated from outside of the semiconductor device 200 and an electromagnetic wave 254 irradiated from inside of the semiconductor device 200 (for example, generated by the electronic components 220) are illustrated. As can be seen, the electromagnetic wave 252 can be reflected by an inclined sidewall and then bounced back by another inclined sidewall on the top surface 240a of the EMI shielding layer 240. That is, the shield protrusions 245 of the EMI shielding layer 240 can increase the number of times the electromagnetic wave 252 is reflected while reducing or preventing the transmission of the electromagnetic wave 252 through the EMI shielding layer 240. As the EMI shielding layer 240 is made of a conductive or magnetic material, the electromagnetic wave 252 can be significantly absorbed during the multiple reflections. As shown in FIG. 2B, the thicknesses of the arrow lines represent the intensity of the electromagnetic waves 252, showing that the intensity of the electromagnetic waves 252 is decreasing. Similarly, the electromagnetic waves 254 can be reflected by an inclined sidewall on the bottom surface 240b of the EMI shielding layer 240 and then bounced back by another inclined sidewall at the same side. Thus, the external electromagnetic wave 252 can be inhibited from entering into the semiconductor device 200, and the electromagnetic wave 254 generated in the semiconductor device 200 can be inhibited from leaking to the outside.

FIG. 2C illustrates another scenario with an electromagnetic wave 252′ and an electromagnetic wave 254′ irradiated towards the top surface 240a and the bottom surface 240b of the EMI shielding layer 240 respectively. The incident directions of the electromagnetic waves 252′ and 254′ are different from those of the electromagnetic waves 252 and 254 shown in FIG. 2B. As can be seen, after several times of reflections by the inclined sidewalls, the electromagnetic waves 252′ and 254′ are trapped in the tip areas of the shield protrusions 245 and can be mostly (e.g., greater than 50%, greater than 60%, greater than 70%, greater than 80%, greater than 90%, greater than 95% or even higher) absorbed by the EMI shielding layer 240, rather than propagating through the shielding layer 240.

FIG. 2D also illustrates an enlarged view of the portion 250 of the semiconductor device 200 shown in FIG. 2A. As shown in FIG. 2D, some inclined sidewalls of the shield protrusions 245 may converge at an upward pointed tip 240c on the top surface 240a of the EMI shielding layer 240, and some inclined sidewalls of the shield protrusions 245 may converge at a downward pointed tip 240d on the bottom surface 240b of the EMI shielding layer 240. As charges tend to accumulate to at metal tips, the pointed tip 240c or 240d can serve as a lightning rod to collect the electromagnetic waves and have an electric field strength much stronger than the electric field at the other positions of the inclined sidewalls. As the EMI shielding layer 240 is made of a conductive material, the electromagnetic waves can be induced toward the pointed tip 240c or 240d and then flow to the ground through the EMI shielding layer 240. Therefore, the shielding performance of the EMI shielding layer 240 can be further increased.

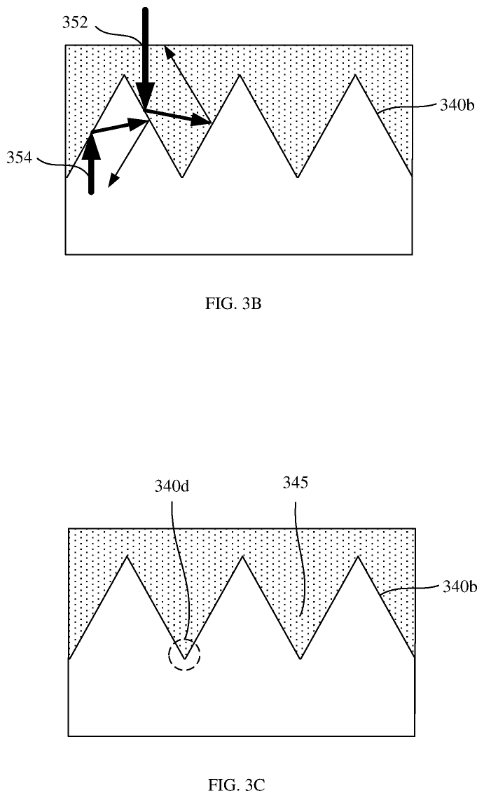

Referring to FIG. 3A, a cross-sectional view of a semiconductor device 300 is illustrated according to an embodiment of the present application. As illustrated in FIG. 3A, the semiconductor device 300 includes a substrate 310, a plurality of electronic components 320, an encapsulant 330, and an EMI shielding layer 340. The substrate 310, the electronic components 320 and the encapsulant 330 are similar to the substrate 210, the electronic components 220 and an encapsulant 230 of FIG. 2A and will not be repeated.

The EMI shielding layer 340 is disposed on the encapsulant 330, and covers the top and lateral surfaces of the encapsulant 330 and the lateral surface of the substrate 310. As shown in FIG. 3A, the EMI shielding layer 340 has a bottom surface 340b conforming to the shape of the plurality of encapsulant protrusions 335 of the encapsulant 330. That is, a plurality of shield protrusions 345 of the EMI shielding layer 340 may extend downwards into respective recesses formed among the encapsulant protrusions 335 of the encapsulant 330. For example, the plurality of shield protrusions 345 may have a pyramidal shape, a conical shape, etc. Different from the EMI shielding layer 240 shown in FIG. 2A, the EMI shielding layer 340 has a planar top surface 340, which facilitates the assembling of the semiconductor device 300 with other devices.

FIG. 3B illustrates an enlarged view of a portion 350 of the semiconductor device 300 shown in FIG. 3A. As can be seen, an electromagnetic wave 352 irradiated from outside of the semiconductor device 300 and an electromagnetic wave 354 irradiated from inside of the semiconductor device 300 can be reflected multiple times by the inclined sidewalls of the shield protrusions 345 at the bottom surface 340b of the EMI shielding layer 340. Accordingly, the external electromagnetic wave 352 can be inhibited from entering into the semiconductor device 300, and the electromagnetic wave 354 generated in the semiconductor device 300 can be inhibited from leaking to the outside.

FIG. 3C also illustrates an enlarged view of the portion 350 of the semiconductor device 300 shown in FIG. 3A. As shown in FIG. 3C, some inclined sidewalls of the shield protrusions 345 may converge at a downward pointed tip 340d on the bottom surface 340b of the EMI shielding layer 340. The electromagnetic waves can be induced toward the pointed tip 340d, and then flow to the ground.

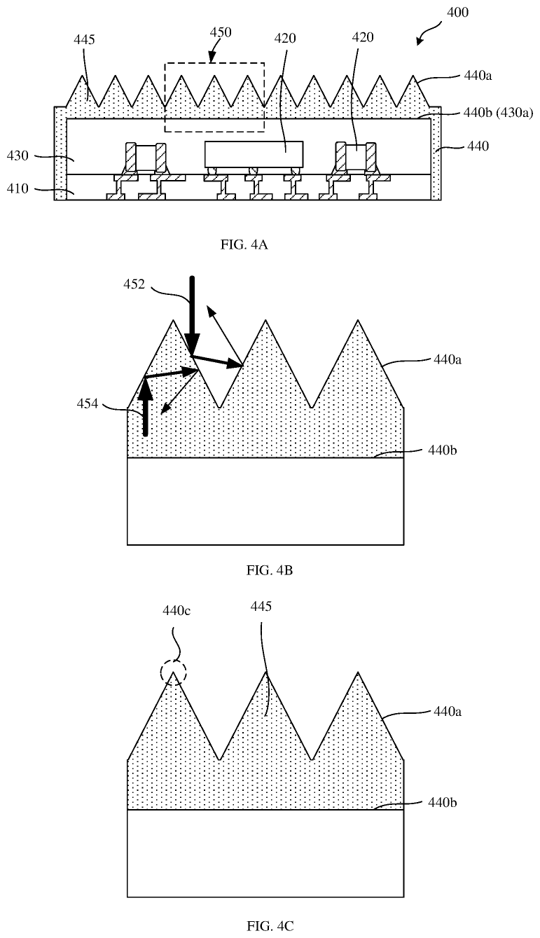

Referring to FIG. 4A, a cross-sectional view of a semiconductor device 400 is illustrated according to an embodiment of the present application. As illustrated in FIG. 4A, the semiconductor device 400 includes a substrate 410, a plurality of electronic components 420, an encapsulant 430, and an EMI shielding layer 440. The substrate 410 and the electronic components 420 are similar to the substrate 210 and the electronic components 220 of FIG. 2A and will not be repeated.

As shown in FIG. 4A, the encapsulant 430 has a planar top surface 430a, and the EMI shielding layer 440 has a planar bottom surface 440b disposed on the planar top surface 430a of the encapsulant 430. The EMI shielding layer 440 covers the top and lateral surfaces of the encapsulant 430 and the lateral surface of the substrate 410. The EMI shielding layer 440 further includes a plurality of shield protrusions 445 extending upwards from its top surface 440a. For example, the plurality of shield protrusions 445 may have a pyramidal shape, a conical shape, etc.

FIG. 4B illustrates an enlarged view of a portion 450 of the semiconductor device 400 shown in FIG. 4A. As can be seen, an electromagnetic wave 452 irradiated from outside of the semiconductor device 400 and an electromagnetic wave 454 irradiated from inside of the semiconductor device 400 can be reflected multiple times by the inclined sidewalls of the shield protrusions 445 at the top surface 440a of the EMI shielding layer 440. Accordingly, the external electromagnetic wave 452 can be inhibited from entering into the semiconductor device 400, and the electromagnetic wave 454 generated in the semiconductor device 400 can be inhibited from leaking to the outside.

FIG. 4C also illustrates an enlarged view of the portion 450 of the semiconductor device 400 shown in FIG. 4A. As shown in FIG. 4C, some inclined sidewalls of the shield protrusions 445 may converge at an upward pointed tip 440c on the top surface 440a of the EMI shielding layer 440. The electromagnetic waves can be induced toward the pointed tip 440c, and then flow to the ground.

In some embodiments of the present application, the semiconductor device may include more than one EMI shielding layer. For example, an additional encapsulant may be disposed on the EMI shielding layer 240 shown in FIG. 2A, the EMI shielding layer 340 shown in FIG. 3A, or the EMI shielding layer 440 shown in FIG. 4A, and then an additional EMI shielding layer can be disposed on the additional encapsulant to further shield EMI or other interferences induced to (or generated by) the electronic components within semiconductor device.

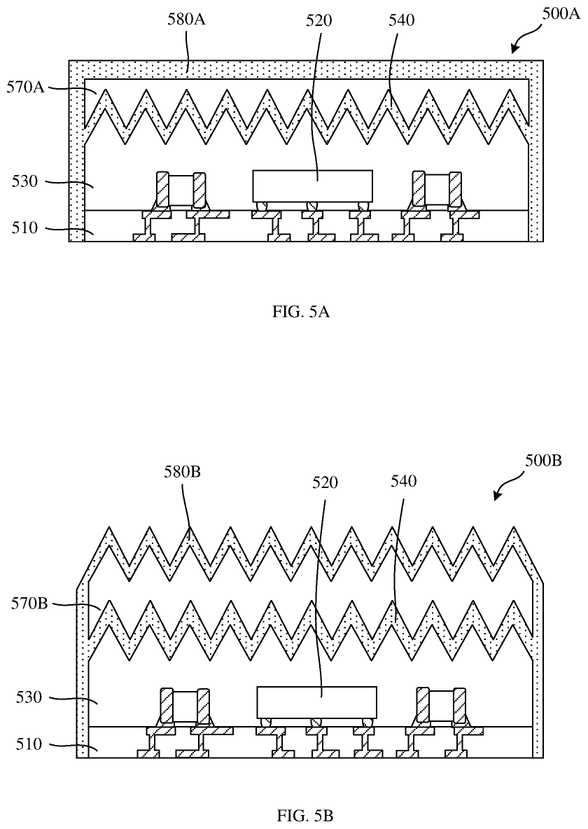

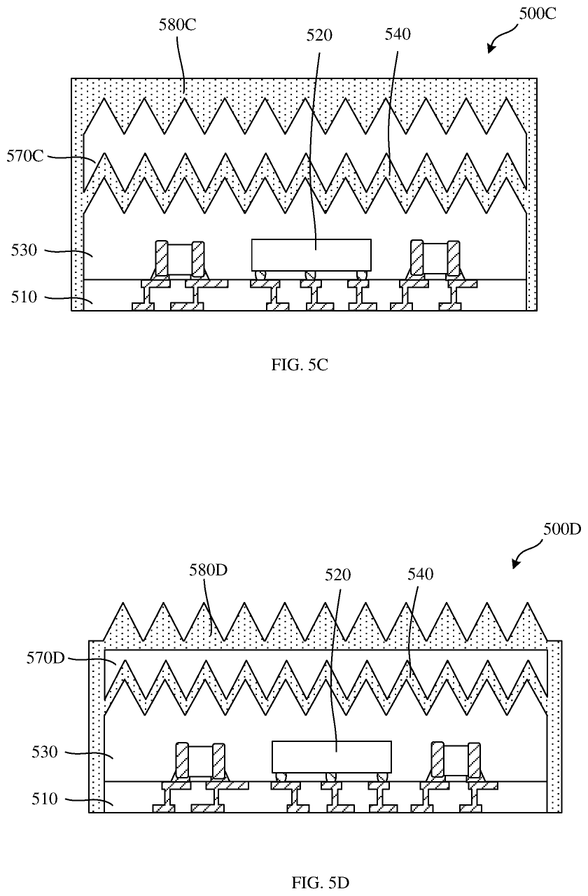

FIGS. 5A-5D illustrate different semiconductor devices 500A, 500B, 500C and 500D having two EMI shielding layers according to some embodiments of the present application. As shown in FIGS. 5A-5D, all the semiconductor devices 500A, 500B, 500C and 500D include a substrate 510, an electronic component 520, a first encapsulant 530, and a first EMI shielding layer 540, which are similar to the substrate 210, the electronic component 220, the encapsulant 230, and the EMI shielding layer 240 shown in FIGS. 2A-2D and will not be repeated.

Referring to FIG. 5A, the semiconductor device 500A includes a second encapsulant 570A disposed on the first EMI shielding layer 540. The second encapsulant 570A fills the recesses on the first EMI shielding layer 540 and has a planar top surface. The semiconductor device 500A further includes a second EMI shielding layer 580A. The second EMI shielding layer 580A covers the planar top surface of the second encapsulant 570A, and also has a planar bottom surface and a planar top surface. Further, the second EMI shielding layer 580A covers the lateral surfaces of the second encapsulant 570A, and is electrically coupled to the first EMI shielding layer 540 to further shield EMI induced to (or generated by) the electronic components 520.

Referring to FIG. 5B, the semiconductor device 500B includes a second encapsulant 570B disposed on the first EMI shielding layer 540. The second encapsulant 570B fills the recesses on the first EMI shielding layer 540, and includes a plurality of encapsulant protrusions at its top surface. Each encapsulant protrusion may have one or more inclined sidewalls converging at a pointed tip. The semiconductor device 500B further includes a second EMI shielding layer 580B. The second EMI shielding layer 580B has a bottom surface conforming to the shape of the plurality of encapsulant protrusions of the second encapsulant 570B, and a top surface parallel to the bottom surface. That is, the second EMI shielding layer 580B also includes a plurality of shield protrusions each having one or more inclined sidewalls converging at a pointed tip. Further, the second EMI shielding layer 580B covers the lateral surfaces of the second encapsulant 570B, and is electrically coupled to the first EMI shielding layer 540.

Referring to FIG. 5C, the semiconductor device 500C includes a second encapsulant 570C disposed on the first EMI shielding layer 540. The second encapsulant 570C fills the recesses on the first EMI shielding layer 540, and includes a plurality of encapsulant protrusions at its top surface. Each encapsulant protrusion may have one or more inclined sidewalls converging at a pointed tip. The semiconductor device 500C further includes a second EMI shielding layer 580C. The second EMI shielding layer 580C has a bottom surface conforming to the shape of the plurality of encapsulant protrusions of the second encapsulant 570C, and a planar top surface. Accordingly, the second EMI shielding layer 580C includes a plurality of shield protrusions each having one or more inclined sidewalls converging at a pointed tip and extending downwards into respective recesses formed among the encapsulant protrusions of the second encapsulant 570C. Further, the second EMI shielding layer 580C covers the lateral surfaces of the second encapsulant 570C, and is electrically coupled to the first EMI shielding layer 540.

Referring to FIG. 5D, the semiconductor device 500D includes a second encapsulant 570D disposed on the first EMI shielding layer 540. The second encapsulant 570D fills the recesses on the first EMI shielding layer 540, and has a planar top surface. The semiconductor device 500D further includes a second EMI shielding layer 580D. The second EMI shielding layer 580D has a planar bottom surface on the planar top surface of the second encapsulant 570D. The second EMI shielding layer 580D further includes a plurality of shield protrusions extending upwards from its top surface. Each shield protrusion has one or more inclined sidewalls converging at a pointed tip. Further, the second EMI shielding layer 580D covers the lateral surfaces of the second encapsulant 570D, and is electrically coupled to the first EMI shielding layer 540.

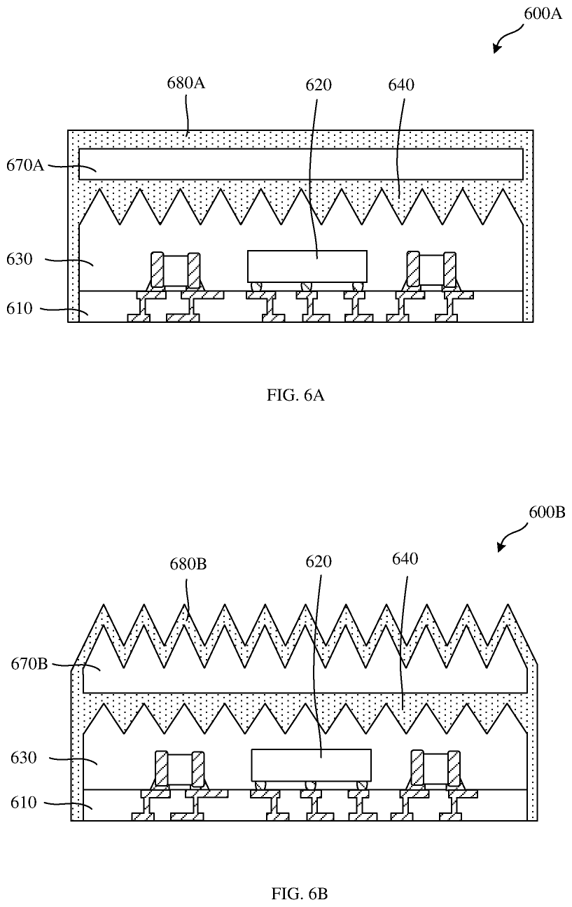

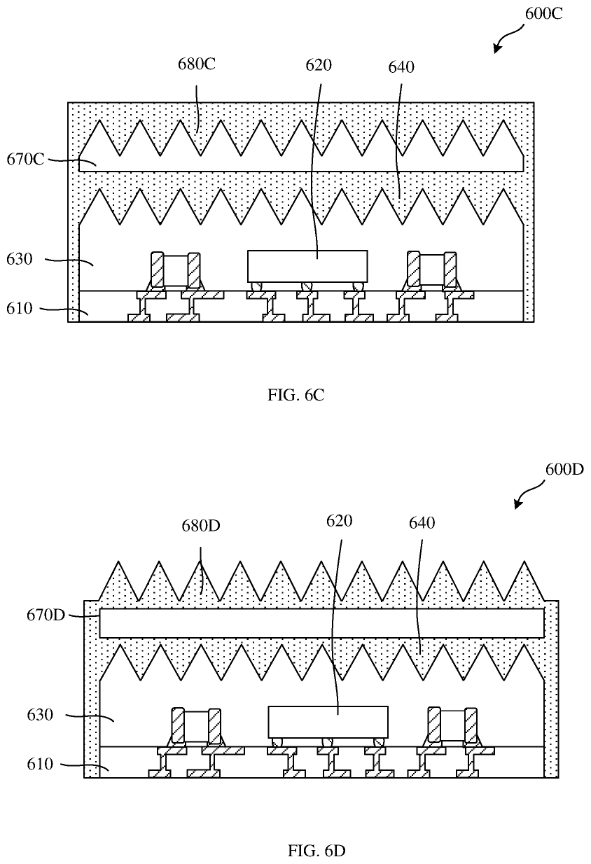

FIGS. 6A-6D illustrate different semiconductor devices 600A, 600B, 600C and 600D having two EMI shielding layers according to some embodiments of the present application. As shown in FIGS. 6A-6D, all the semiconductor devices 600A, 600B, 600C and 600D include a substrate 610, an electronic component 620, a first encapsulant 630, and a first EMI shielding layer 640, which are similar to the substrate 310, the electronic component 320, the encapsulant 330, and the EMI shielding layer 340 shown in FIGS. 3A-3C and will not be repeated.

Referring to FIG. 6A, the semiconductor device 600A includes a second encapsulant 670A disposed on the planar top surface of the first EMI shielding layer 640. The second encapsulant 670A also has a planar top surface. The semiconductor device 600A further includes a second EMI shielding layer 680A. The second EMI shielding layer 680A covers the planar top surface of the second encapsulant 670A, and also has a planar bottom surface and a planar top surface. Further, the second EMI shielding layer 680A covers the lateral surfaces of the second encapsulant 670A, and is electrically coupled to the first EMI shielding layer 640.

Referring to FIG. 6B, the semiconductor device 600B includes a second encapsulant 670B disposed on the planar top surface of the first EMI shielding layer 640. The second encapsulant 670B includes a plurality of encapsulant protrusions at its top surface. Each encapsulant protrusion may have one or more inclined sidewalls converging at a pointed tip. The semiconductor device 600B further includes a second EMI shielding layer 680B. The second EMI shielding layer 680B has a bottom surface conforming to the shape of the plurality of encapsulant protrusions of the second encapsulant 670B, and a top surface parallel to the bottom surface. That is, the second EMI shielding layer 680B also includes a plurality of shield protrusions each having one or more inclined sidewalls converging at a pointed tip. Further, the second EMI shielding layer 680B covers the lateral surfaces of the second encapsulant 670B, and is electrically coupled to the first EMI shielding layer 640.

Referring to FIG. 6C, the semiconductor device 600C includes a second encapsulant 670C disposed on the planar top surface of the first EMI shielding layer 640. The second encapsulant 670C includes a plurality of encapsulant protrusions at its top surface. Each encapsulant protrusion may have one or more inclined sidewalls converging at a pointed tip. The semiconductor device 600C further includes a second EMI shielding layer 680C. The second EMI shielding layer 680C has a bottom surface conforming to the plurality of encapsulant protrusions of the second encapsulant 670C, and a planar top surface. Accordingly, the second EMI shielding layer 680C includes a plurality of shield protrusions each having one or more inclined sidewalls converging at a pointed tip and extending downwards into respective recesses formed among the encapsulant protrusions of the second encapsulant 670C. Further, the second EMI shielding layer 680C covers the lateral surfaces of the second encapsulant 670C, and is electrically coupled to the first EMI shielding layer 640.

Referring to FIG. 6D, the semiconductor device 600D includes a second encapsulant 670D disposed on the planar top surface of the first EMI shielding layer 640. The second encapsulant 670D also has a planar top surface. The semiconductor device 600D further includes a second EMI shielding layer 680D. The second EMI shielding layer 680D has a planar bottom surface on the planar top surface of the second encapsulant 670D. The second EMI shielding layer 680D further includes a plurality of shield protrusions extending upwards from its top surface. Each shield protrusion has one or more inclined sidewalls converging at a pointed tip. Further, the second EMI shielding layer 680D covers the lateral surfaces of the second encapsulant 670D, and is electrically coupled to the first EMI shielding layer 640.

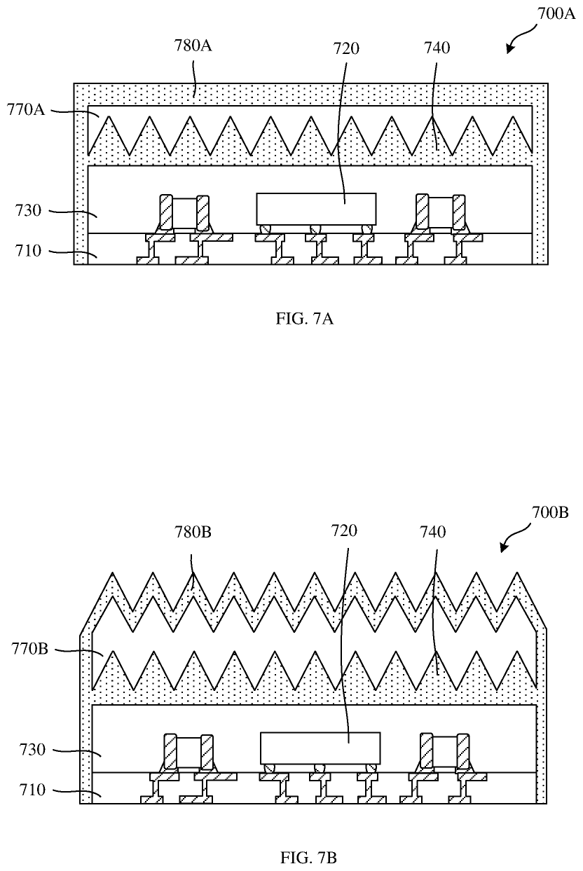

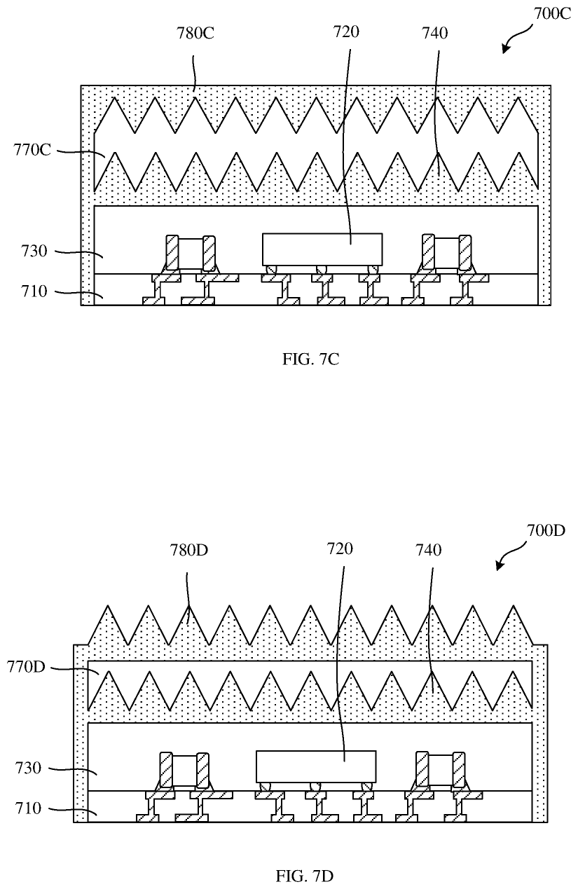

FIGS. 7A-7D illustrate different semiconductor devices 700A, 700B, 700C and 700D having two EMI shielding layers according to some embodiments of the present application. As shown in FIGS. 7A-7D, all the semiconductor devices 700A, 700B, 700C and 700D include a substrate 710, an electronic component 720, a first encapsulant 730, and a first EMI shielding layer 740, which are similar to the substrate 410, the electronic component 420, the encapsulant 430, and the EMI shielding layer 440 shown in FIGS. 4A-4C and will not be repeated.

Referring to FIG. 7A, the semiconductor device 700A includes a second encapsulant 770A disposed on the first EMI shielding layer 740. The second encapsulant 770A fills the recesses on the first EMI shielding layer 740 and has a planar top surface. The semiconductor device 700A further includes a second EMI shielding layer 780A. The second EMI shielding layer 780A covers the planar top surface of the second encapsulant 770A, and also has a planar bottom surface and a planar top surface. Further, the second EMI shielding layer 780A covers the lateral surfaces of the second encapsulant 770A, and is electrically coupled to the first EMI shielding layer 740 to further shield EMI induced to (or generated by) the electronic components 720.

Referring to FIG. 7B, the semiconductor device 700B includes a second encapsulant 770B disposed on the first EMI shielding layer 740. The second encapsulant 770B fills the recesses on the first EMI shielding layer 740, and includes a plurality of encapsulant protrusions at its top surface. Each encapsulant protrusion may have one or more inclined sidewalls converging at a pointed tip. The semiconductor device 700B further includes a second EMI shielding layer 780B. The second EMI shielding layer 780B has a bottom surface conforming to the plurality of encapsulant protrusions of the second encapsulant 770B, and a top surface parallel to the bottom surface. That is, the second EMI shielding layer 780B also includes a plurality of shield protrusions each having one or more inclined sidewalls converging at a pointed tip. Further, the second EMI shielding layer 780B covers the lateral surfaces of the second encapsulant 770B, and is electrically coupled to the first EMI shielding layer 740.

Referring to FIG. 7C, the semiconductor device 700C includes a second encapsulant 770C disposed on the first EMI shielding layer 740. The second encapsulant 770C fills the recesses on the first EMI shielding layer 740, and includes a plurality of encapsulant protrusions at its top surface. Each encapsulant protrusion may have one or more inclined sidewalls converging at a pointed tip. The semiconductor device 700C further includes a second EMI shielding layer 780C. The second EMI shielding layer 780C has a bottom surface conforming to the plurality of encapsulant protrusions of the second encapsulant 770C, and a planar top surface. Accordingly, the second EMI shielding layer 780C includes a plurality of shield protrusions each having one or more inclined sidewalls converging at a pointed tip and extending downwards into respective recesses formed among the encapsulant protrusions of the second encapsulant 770C. Further, the second EMI shielding layer 780C covers the lateral surfaces of the second encapsulant 770C, and is electrically coupled to the first EMI shielding layer 740.

Referring to FIG. 7D, the semiconductor device 700D includes a second encapsulant 770D disposed on the first EMI shielding layer 740. The second encapsulant 770D fills the recesses on the first EMI shielding layer 740, and has a planar top surface. The semiconductor device 700D further includes a second EMI shielding layer 780D. The second EMI shielding layer 780D has a planar bottom surface disposed on the planar top surface of the second encapsulant 770D. The second EMI shielding layer 780D further includes a plurality of shield protrusions extending upwards from its top surface. Each shield protrusion has one or more inclined sidewalls converging at a pointed tip. Further, the second EMI shielding layer 780D covers the lateral surfaces of the second encapsulant 770D, and is electrically coupled to the first EMI shielding layer 740.

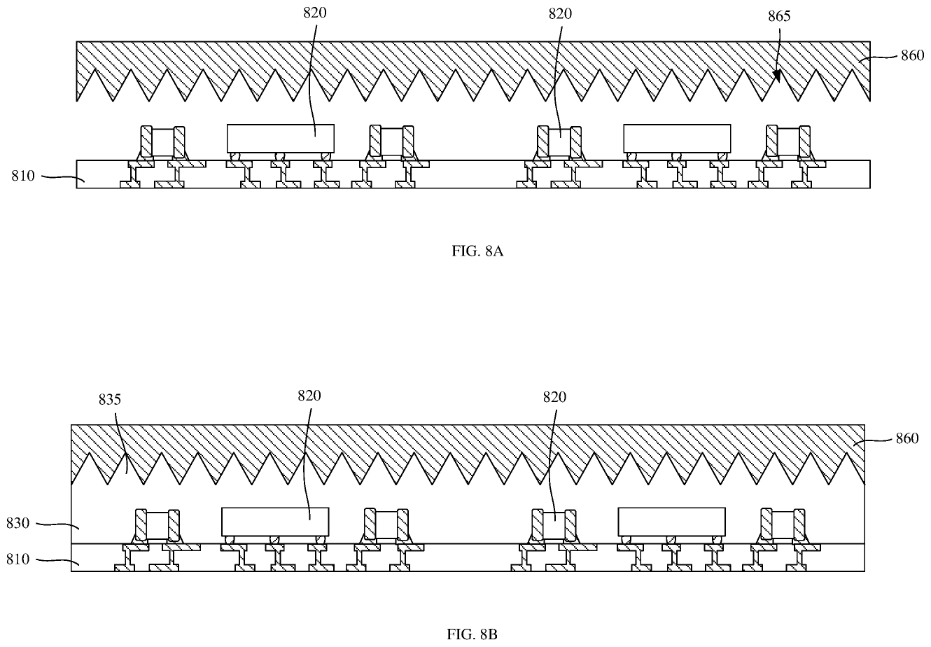

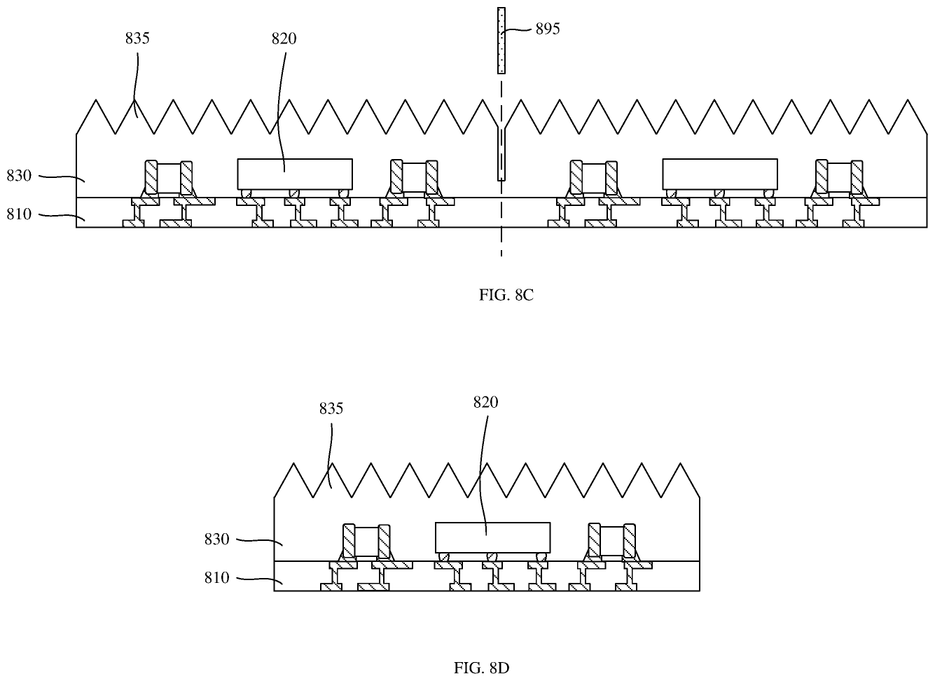

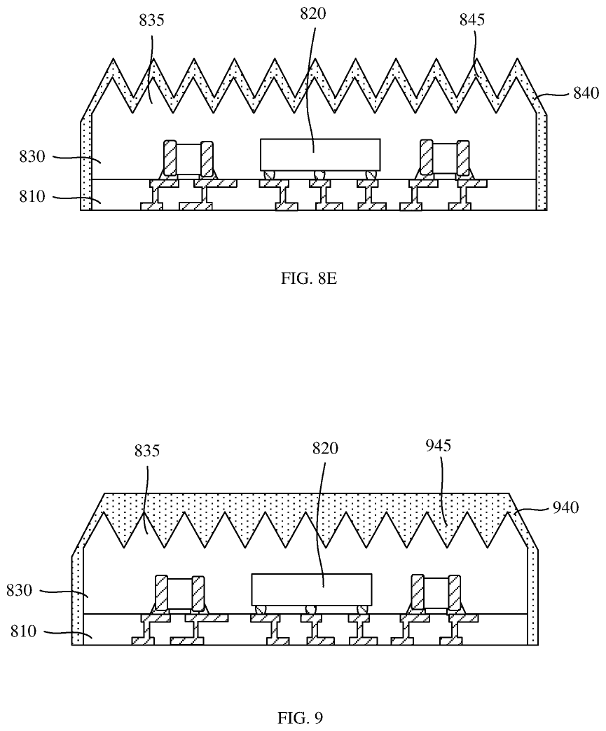

Referring to FIGS. 8A to 8E, various steps of a method for forming a semiconductor device are illustrated according to an embodiment of the present application. For example, the method may be used to form the semiconductor device 200 shown in FIG. 2A. In the following, the method will be described with reference to FIGS. 8A to 8E in more details.

As shown in FIG. 8A, a package is provided. The package includes a substrate 810 and a plurality of electronic components 820. The electronic components 820 are mounted on the top surface of the substrate 810. There may be a plurality of singulation channels (not shown) on the substrate 810, and the singulation channels can provide cutting areas to singulate the substrate 810 into individual semiconductor devices. The substrate 810 and the electronic components 820 are similar as the substrate 210 and the electronic components 220 shown in FIG. 2A, respectively, and will not be described in detail herein. A mold 860 is also provided to form an encapsulant on the package. As shown in FIG. 8A, the mold 860 includes a plurality of recesses 865 exposed from a bottom surface of the mold 860.

Afterwards, as shown in FIG. 8B, the mold 860 and the package are engaged with each other. Then, an encapsulation material is injected into the mold 860 to form an encapsulant 830 on the substrate 810 using compressive molding, transfer molding, liquid encapsulant molding, or other suitable process. The encapsulant includes a plurality of encapsulant protrusions 835 formed in the plurality of recesses of the mold 860, respectively.

Afterwards, the substrate 810 shown in FIG. 8C is singulated into individual devices as shown in FIG. 8D. For example, as shown in FIG. 8C, the substrate 810 can be singulated into individual devices at singulation channels using a saw blade 895. In some other examples, a laser cutting tool can also be used to singulate the substrate 810.

Referring to FIG. 8E, an EMI shielding layer 840 is formed on the encapsulant 830 using sputtering, spraying, printing, plating, evaporation, CVD, PVD, or other suitable process. The EMI shielding layer 840 covers the top and lateral surfaces of the encapsulant 830 and the lateral surface of the substrate 810. The EMI shielding layer 840 has a bottom surface conforming to the shape of the plurality of encapsulant protrusions 835, and a top surface parallel to the bottom surface of the EMI shielding layer 840. That is, the EMI shielding layer 840 also includes a plurality of shield protrusions 845 each having one or more inclined sidewalls converging at a pointed tip.

In some other examples, after the substrate 810 shown in FIG. 8C is singulated into individual devices as shown in FIG. 8D, an EMI material can be deposited on the encapsulant 830 to fully fill the recessed among the encapsulant protrusions 835 of the encapsulant 830. As shown in FIG. 9, the EMI material may form another EMI shielding layer 940. The EMI shielding layer 940 covers the top and lateral surfaces of the encapsulant 830 and the lateral surface of the substrate 810. The EMI shielding layer 940 has a bottom surface conforming to the shape of the plurality of encapsulant protrusions of the encapsulant 830, and a planar top surface. Accordingly, the EMI shielding layer 940 includes a plurality of shield protrusions 945 each having one or more inclined sidewalls converging at a pointed tip and extending downwards into the respective recesses formed among the encapsulant protrusions 835 of the encapsulant 830. As can be seen, the various steps shown in FIGS. 8A-8D and FIG. 9 can be used to form the semiconductor device 300 shown in FIG. 3A.

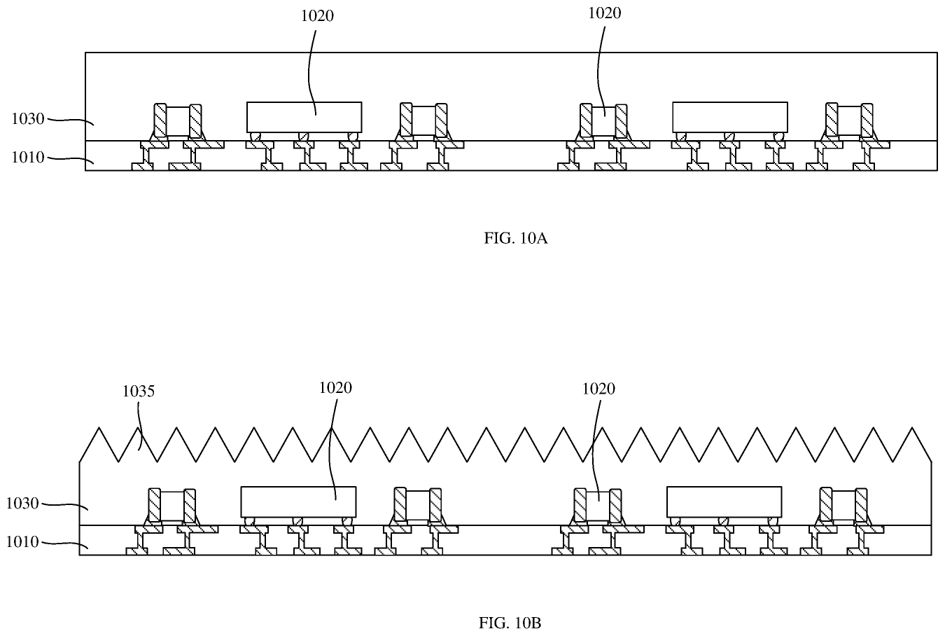

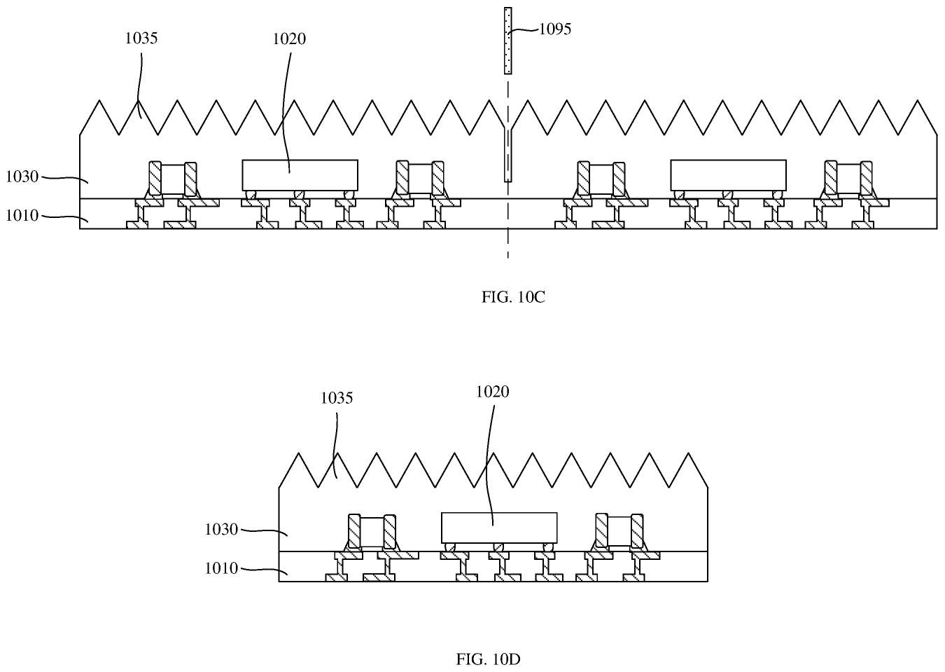

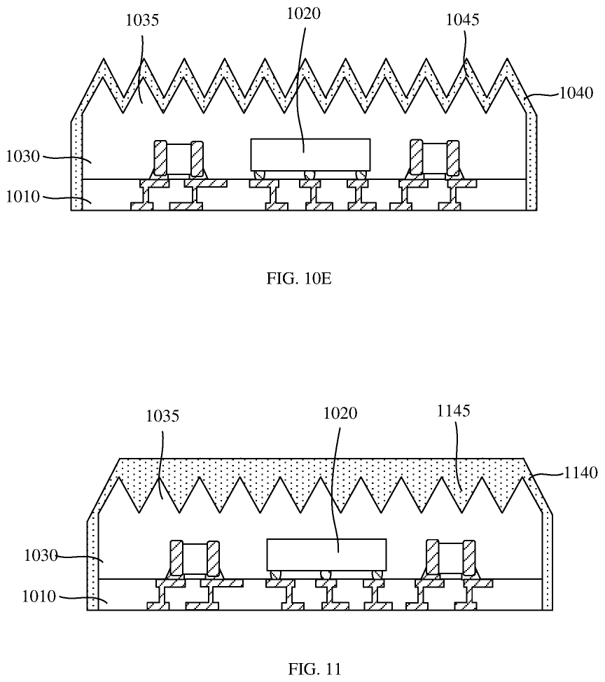

Referring to FIGS. 10A to 10E, various steps of a method for forming a semiconductor device are illustrated according to another embodiment of the present application. For example, the method can also be used to form the semiconductor device 200 shown in FIG. 2A. In the following, the method will be described with reference to FIGS. 10A to 10E in more details.

As shown in FIG. 10A, a package is provided. The package includes a substrate 1010 and a plurality of electronic components 1020. The electronic components 1020 are mounted on the top surface of the substrate 1010. An encapsulant 1030 is formed on the substrate 1010 and encapsulates the electronic components 1020. For example, a mold with a planar bottom surface may be provided and engaged with the package, and then encapsulation material is injected into the mold to form the encapsulant 1030 on the substrate 1010 using compressive molding, transfer molding, liquid encapsulant molding, or other suitable process.

Afterwards, as shown in FIG. 10B, the top surface of the encapsulant 1030 is patterned to form a plurality of encapsulant protrusions 1035. Each encapsulant protrusion 1035 may have one or more inclined sidewalls converging at a pointed tip. In some examples, a laser ablation process may be employed to form the plurality of encapsulant protrusions 1035. In some examples, a chemical texturing process may be employed to form the plurality of encapsulant protrusions 1035.

Afterwards, the substrate 1010 shown in FIG. 10C is singulated into individual devices as shown in FIG. 10D. For example, as shown in FIG. 10C, the substrate 1010 can be singulated into individual devices at singulation channels using a saw blade 1095. In some other examples, a laser cutting tool can also be used to singulate the substrate 1010.

Referring to FIG. 10E, an EMI shielding layer 1040 is formed on the encapsulant 1030 using sputtering, spraying, printing, plating, evaporation, CVD, PVD, or other suitable process. The EMI shielding layer 1040 covers the top and lateral surfaces of the encapsulant 1030 and the lateral surface of the substrate 1010. The EMI shielding layer 1040 has a bottom surface conforming to the shape of the plurality of encapsulant protrusions 1035 of the encapsulant 1030, and a top surface parallel to the bottom surface of the EMI shielding layer 1040. That is, the EMI shielding layer 1040 also includes a plurality of shield protrusions 1045 each having one or more inclined sidewalls converging at a pointed tip.

In some other examples, after the substrate 1010 shown in FIG. 10C is singulated into individual devices as shown in FIG. 10D, an EMI material can be deposited to fully fill the recessed formed among the encapsulant protrusions 1035 of the encapsulant 1030. As shown in FIG. 11, the EMI material may form another EMI shielding layer 1140. The EMI shielding layer 1140 covers the top and lateral surfaces of the encapsulant 1030 and the lateral surface of the substrate 1010. The EMI shielding layer 1140 has a bottom surface conforming to the shape of the plurality of encapsulant protrusions of the encapsulant 1030, and a planar top surface. Accordingly, the EMI shielding layer 1140 includes a plurality of shield protrusions 1145 each having one or more inclined sidewalls converging at a pointed tip and extending downwards into the respective recesses formed among the encapsulant protrusions 1035 of the encapsulant 1030. As can be seen, the various steps shown in FIGS. 10A-10D and FIG. 11 can also be used to form the semiconductor device 300 shown in FIG. 3A.

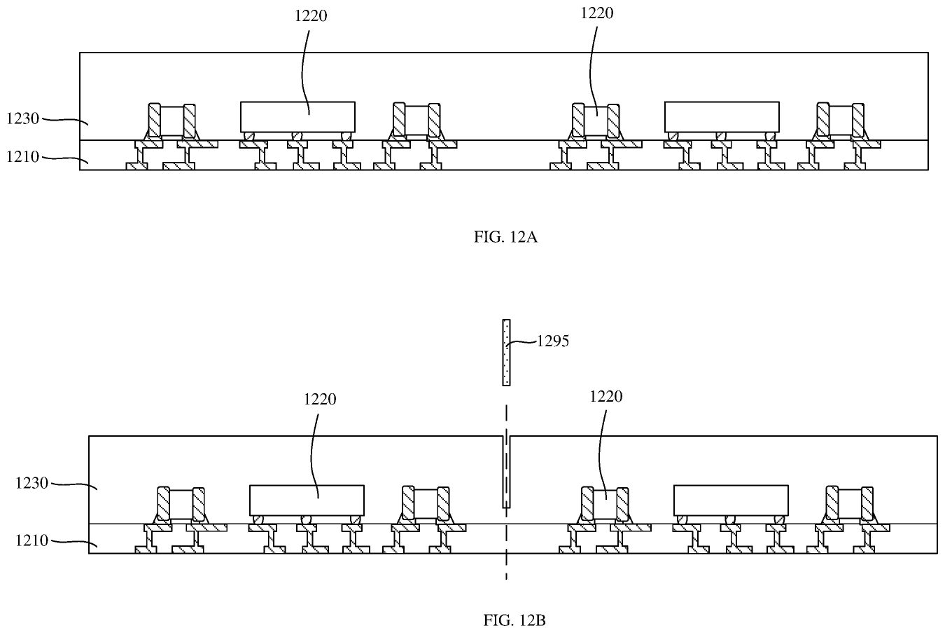

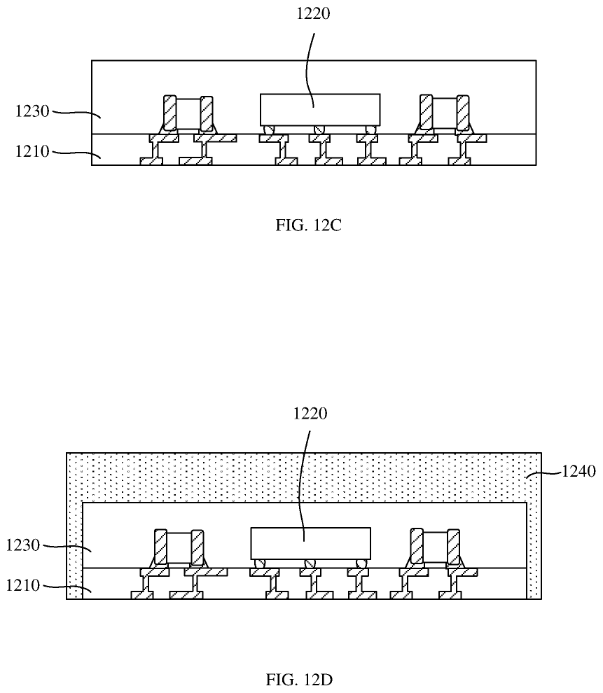

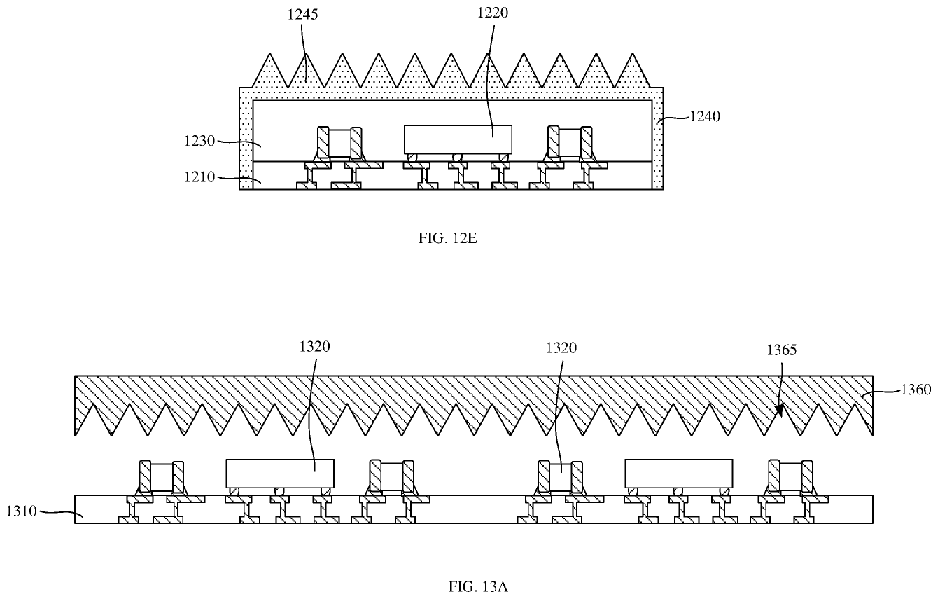

Referring to FIGS. 12A to 12E, various steps of a method for forming a semiconductor device are illustrated according to an embodiment of the present application. For example, the method can be used to form the semiconductor device 400 shown in FIG. 4A. In the following, the method will be described with reference to FIGS. 12A to 12E in more details.

As shown in FIG. 12A, a package is provided. The package includes a substrate 1210 and a plurality of electronic components 1220. The electronic components 1220 are mounted on the top surface of the substrate 1210. An encapsulant 1230 is formed on the substrate 1210 and encapsulates the electronic components 1220. For example, a mold with a planar bottom surface may be provided and engaged with the package, and then an encapsulation material is injected into the mold to form the encapsulant 1230 on the substrate 1210 using compressive molding, transfer molding, liquid encapsulant molding, or other suitable process.

Afterwards, the substrate 1210 shown in FIG. 12B is singulated into individual devices as shown in FIG. 12C. For example, as shown in FIG. 12B, the substrate 1210 can be singulated into individual devices at singulation channels using a saw blade 1295. In some other examples, a laser cutting tool can also be used to singulate the substrate 1210.

Afterwards, referring to FIG. 12D, an EMI shielding layer 1240 is formed on the encapsulant 1230 using sputtering, spraying, printing, plating, evaporation, CVD, PVD, or other suitable process. The EMI shielding layer 1240 covers the top and lateral surfaces of the encapsulant 1230 and the lateral surface of the substrate 1210.

Referring to FIG. 12E, the top surface of the EMI shielding layer 1240 is patterned to form a plurality of shield protrusions 1245. Each shield protrusions 1245 may have one or more inclined sidewalls converging at a pointed tip. In some examples, a laser ablation process may be employed to form the plurality of shield protrusions 1245. In some examples, a chemical texturing process may be employed to form the plurality of shield protrusions 1245.

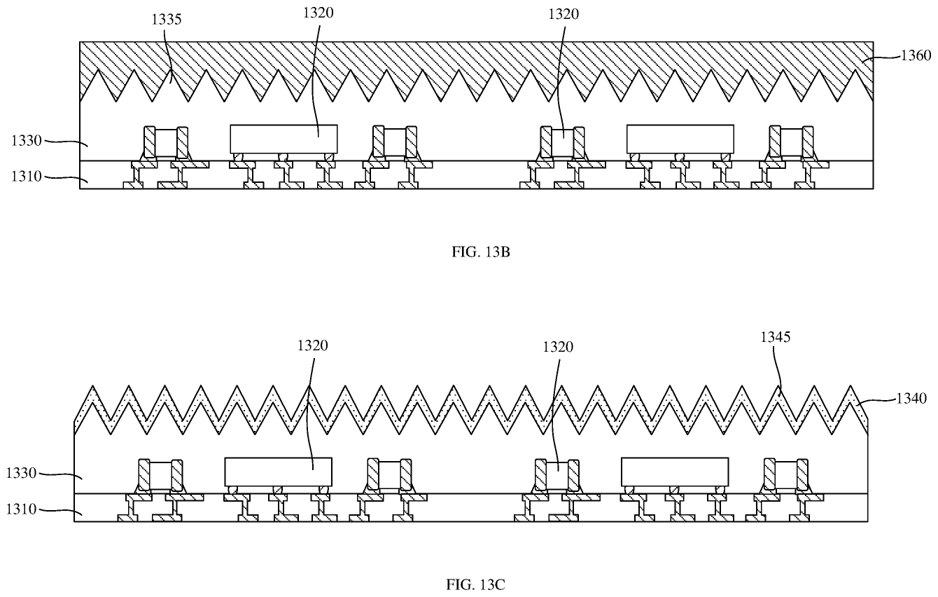

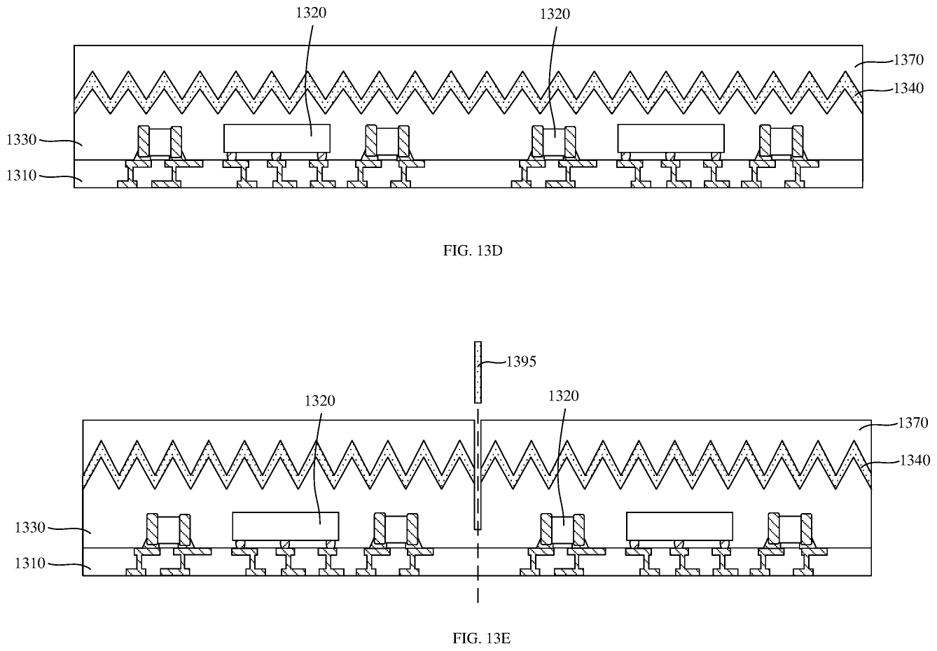

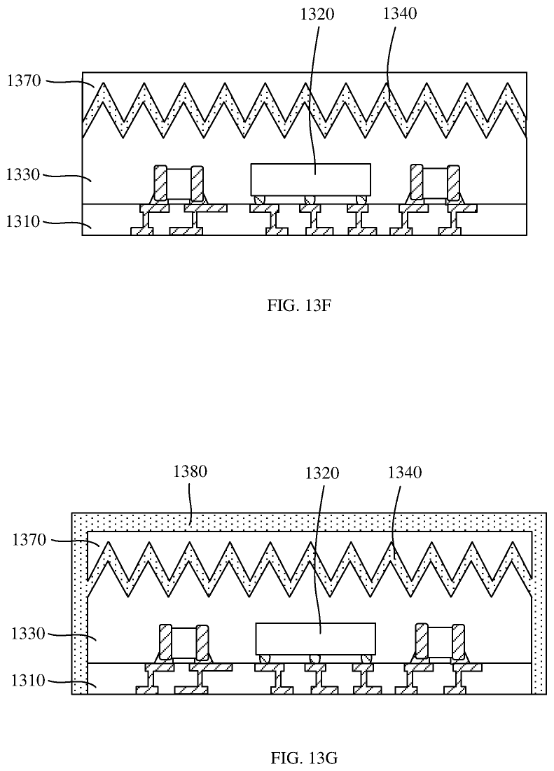

Referring to FIGS. 13A to 13G, various steps of a method for forming a semiconductor device are illustrated according to an embodiment of the present application. For example, the method may be used to form the semiconductor device 500A shown in FIG. 5A. In the following, the method will be described with reference to FIGS. 13A to 13G in more details.

As shown in FIG. 13A, a package is provided. The package includes a substrate 1310 and a plurality of electronic components 1320. The electronic components 1320 are mounted on the top surface of the substrate 1310. A mold 1360 is also provided to form a first encapsulant on the package. As shown in FIG. 13A, the mold 1360 includes a plurality of recesses 1365 exposed from a bottom surface of the mold 1360.

As shown in FIG. 13B, the mold 1360 and the package are engaged with each other. Then, an encapsulation material is injected into the mold 1360 to form a first encapsulant 1330 on the substrate 1310 using compressive molding, transfer molding, liquid encapsulant molding, or other suitable process. The first encapsulant 1330 includes a plurality of encapsulant protrusions 1335 formed in the plurality of recesses of the mold 1360, respectively.

Afterwards, referring to FIG. 13C, a first EMI shielding layer 1340 is formed on the first encapsulant 1330 using sputtering, spraying, printing, plating, evaporation, CVD, PVD, or other suitable process. The first EMI shielding layer 1340 has a bottom surface conforming to the shape of the plurality of encapsulant protrusions 1335 of the first encapsulant 1330, and a top surface parallel to the bottom surface. That is, the first EMI shielding layer 1340 also includes a plurality of shield protrusions 1345 each having one or more inclined sidewalls converging at a pointed tip.

As shown in FIG. 13D, a second encapsulant 1370 is formed on the first EMI shielding layer 1340. For example, a mold with a planar bottom surface may be provided and engaged with the package, and then an encapsulation material is injected into the mold to form the second encapsulant 1370. Thus, the second encapsulant 1370 may also has a planar top surface.

Afterwards, the package shown in FIG. 13E is singulated into individual devices as shown in FIG. 13F. For example, as shown in FIG. 13E, the substrate 1310 can be singulated into individual devices at singulation channels using a saw blade 1395. In some other examples, a laser cutting tool can also be used to singulate the substrate 1310.

Afterwards, referring to FIG. 13G, a second EMI shielding layer 1380 is formed on the second encapsulant 1370. The second EMI shielding layer 1380 covers the top and lateral surfaces of the second encapsulant 1370, the lateral surfaces of the first encapsulant 1330, and the lateral surface of the substrate 1310. The second EMI shielding layer 1380 also covers and electrically connects to the exposed lateral surfaces of the first EMI shielding layer 1340. As the second encapsulant 1370 has a planar top surface, the second EMI shielding layer 1380 may also have a planar top surface.

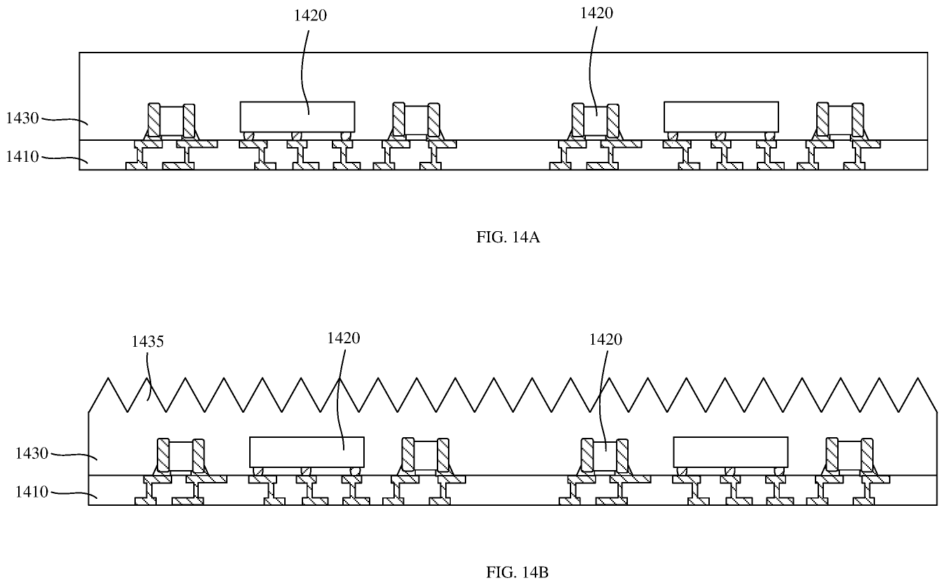

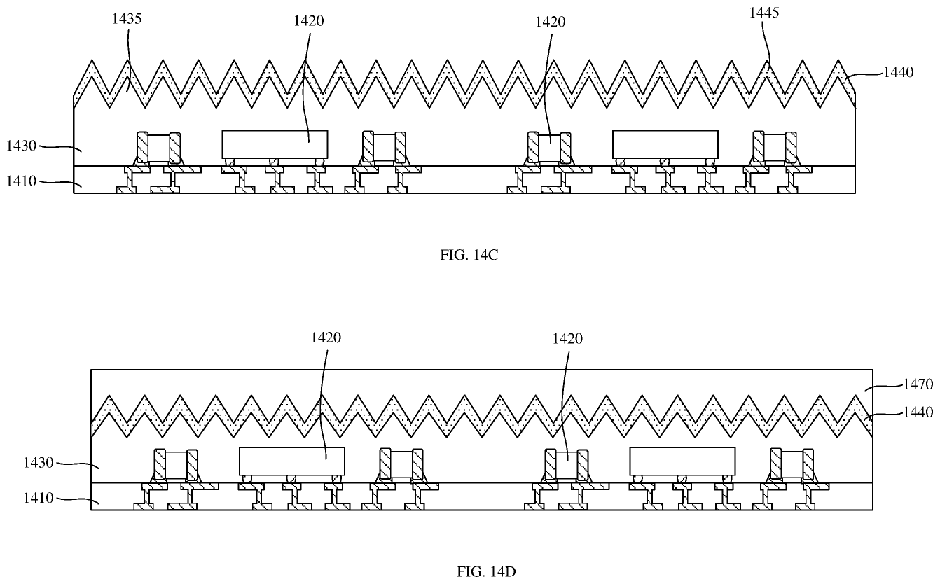

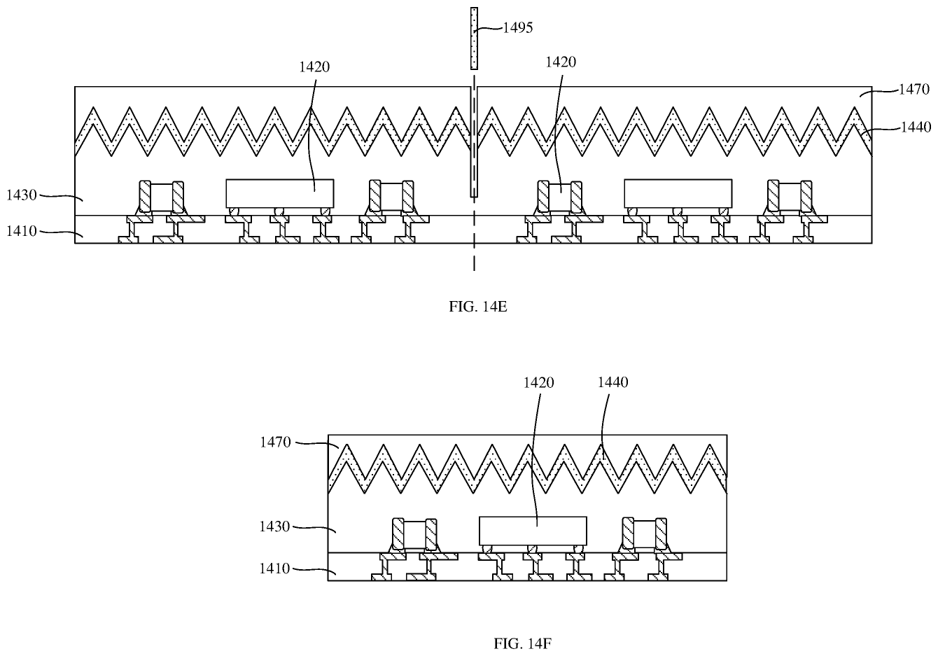

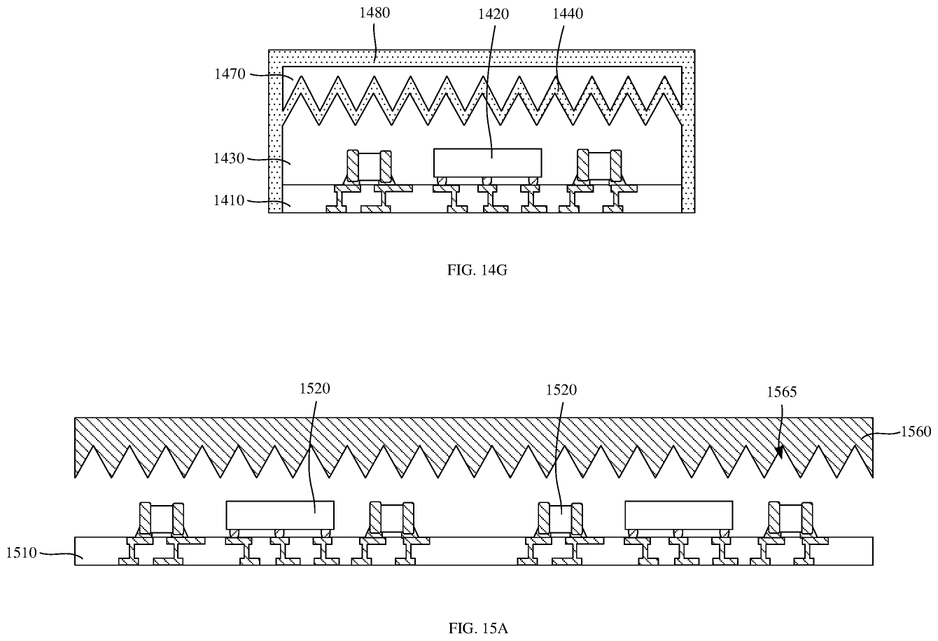

Referring to FIGS. 14A to 14G, various steps of a method for forming a semiconductor device are illustrated according to an embodiment of the present application. For example, the method can also be used to form the semiconductor device 500A shown in FIG. 5A. In the following, the method will be described with reference to FIGS. 14A to 14G in more details.

As shown in FIG. 14A, a package is provided. The package includes a substrate 1410 and a plurality of electronic components 1420. The electronic components 1420 are mounted on the top surface of the substrate 1410. A first encapsulant 1430 is formed on the substrate 1410 and encapsulates the electronic components 1420. For example, a mold with a planar bottom surface may be provided and engaged with the package, and then encapsulation material is injected into the mold to form the first encapsulant 1430 on the substrate 1410 using compressive molding, transfer molding, liquid encapsulant molding, or other suitable process.

Afterwards, as shown in FIG. 14B, the top surface of the first encapsulant 1430 is patterned to form a plurality of encapsulant protrusions 1435. Each encapsulant protrusion 1435 may have one or more inclined sidewalls converging at a pointed tip. In some examples, a laser ablation process may be employed to form the plurality of encapsulant protrusions 1435. In some examples, a chemical texturing process may be employed to form the plurality of encapsulant protrusions 1435.

Afterwards, referring to FIG. 14C, a first EMI shielding layer 1440 is formed on the first encapsulant 1430 using sputtering, spraying, printing, plating, evaporation, CVD, PVD, or other suitable process. The first EMI shielding layer 1440 has a bottom surface conforming to the shape of the plurality of encapsulant protrusions 1435 of the first encapsulant 1430, and a top surface parallel to the bottom surface. That is, the first EMI shielding layer 1440 also includes a plurality of shield protrusions 1445 each having one or more inclined sidewalls converging at a pointed tip.

As shown in FIG. 14D, a second encapsulant 1470 is formed on the first EMI shielding layer 1440. For example, a mold with a planar bottom surface may be provided and engaged with the package, and then an encapsulation material is injected into the mold to form the second encapsulant 1470. Thus, the second encapsulant 1470 may also has a planar top surface.

Afterwards, the package shown in FIG. 14E is singulated into individual devices as shown in FIG. 14F. For example, as shown in FIG. 14E, the substrate 1410 can be singulated into individual devices at singulation channels using a saw blade 1495. In some other examples, a laser cutting tool can also be used to singulate the substrate 1410.

Afterwards, referring to FIG. 14G, a second EMI shielding layer 1480 is formed on the second encapsulant 1470. The second EMI shielding layer 1480 covers the top and lateral surfaces of the second encapsulant 1470, the lateral surfaces of the first encapsulant 1430, and the lateral surface of the substrate 1410. The second EMI shielding layer 1480 also covers and electrically connects to the exposed lateral surfaces of the first EMI shielding layer 1440. As the second encapsulant 1470 has a planar top surface, the second EMI shielding layer 1480 may also have a planar top surface.

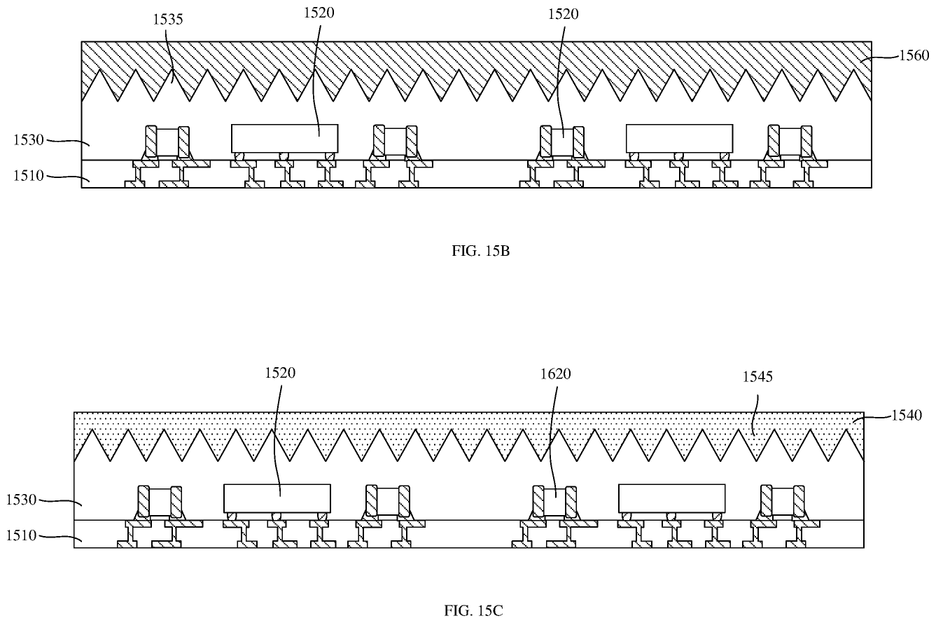

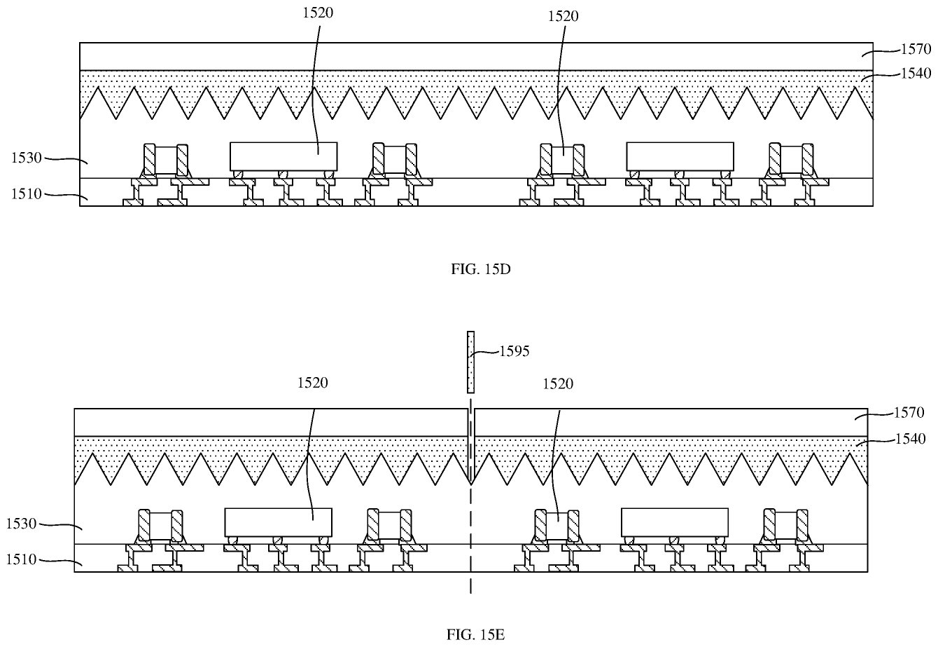

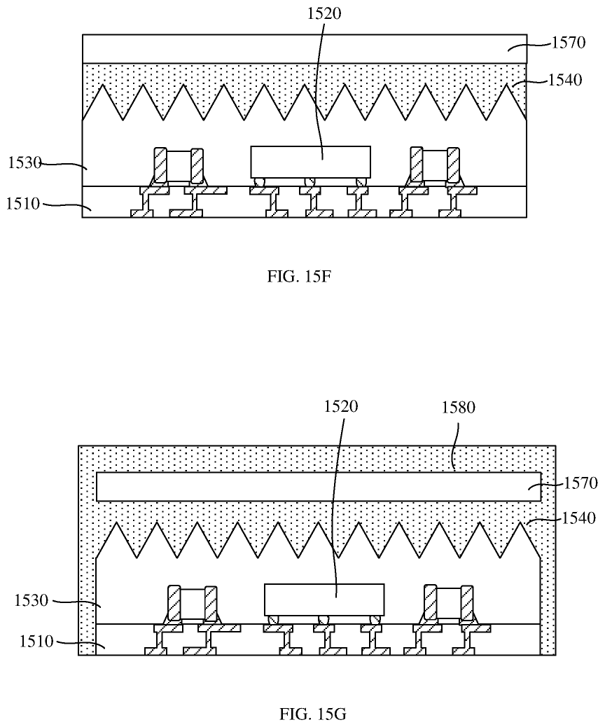

Referring to FIGS. 15A to 15G, various steps of a method for forming a semiconductor device are illustrated according to an embodiment of the present application. For example, the method may be used to form the semiconductor device 600A shown in FIG. 6A. In the following, the method will be described with reference to FIGS. 15A to 15G in more details.

As shown in FIG. 15A, a package is provided. The package includes a substrate 1510 and a plurality of electronic components 1520. The electronic components 1520 are mounted on the top surface of the substrate 1510. A mold 1560 is also provided to form a first encapsulant on the package. As shown in FIG. 15A, the mold 1560 includes a plurality of recesses 1565 exposed from a bottom surface of the mold 1560.

As shown in FIG. 15B, the mold 1560 and the package are engaged. Then, an encapsulation material is injected into the mold 1560 to form a first encapsulant 1530 on the substrate 1510 using compressive molding, transfer molding, liquid encapsulant molding, or other suitable process. The first encapsulant 1530 includes a plurality of encapsulant protrusions 1535 formed in the plurality of recesses of the mold 1560.

Afterwards, referring to FIG. 15C, a first EMI shielding layer 1540 is formed on the first encapsulant 1530 using sputtering, spraying, printing, plating, evaporation, CVD, PVD, or other suitable process. The first EMI shielding layer 1540 has a bottom surface conforming to the shape of the plurality of encapsulant protrusions 1535 of the first encapsulant 1530, and a planar top surface. That is, a plurality of shield protrusions 1545 of the first EMI shielding layer 1540 may extend downwards into respective recesses formed among the encapsulant protrusions 1535 of the first encapsulant 1530.

As shown in FIG. 15D, a second encapsulant 1570 is formed on the first EMI shielding layer 1540. For example, a mold with a planar bottom surface may be provided and engaged with the package, and then encapsulation material is injected into the mold to form the second encapsulant 1570. Thus, the second encapsulant 1570 may also has a planar top surface.

Afterwards, the package shown in FIG. 15E is singulated into individual devices as shown in FIG. 15F. For example, as shown in FIG. 15E, the substrate 1510 can be singulated into individual devices at singulation channels using a saw blade 1595. In some other examples, a laser cutting tool can also be used to singulate the substrate 1510.

Afterwards, referring to FIG. 15G, a second EMI shielding layer 1580 is formed on the second encapsulant 1570. The second EMI shielding layer 1580 covers the top and lateral surfaces of the second encapsulant 1570, the lateral surfaces of the first encapsulant 1530, and the lateral surface of the substrate 1510. The second EMI shielding layer 1580 also covers and electrically connects to the exposed lateral surfaces of the first EMI shielding layer 1540. As the second encapsulant 1570 has a planar top surface, the second EMI shielding layer 1580 may also have a planar top surface.

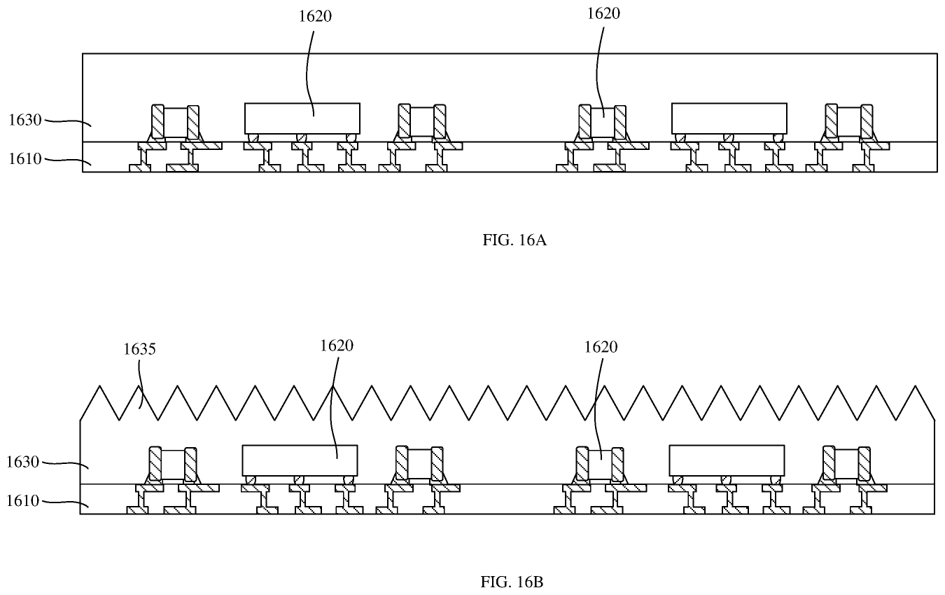

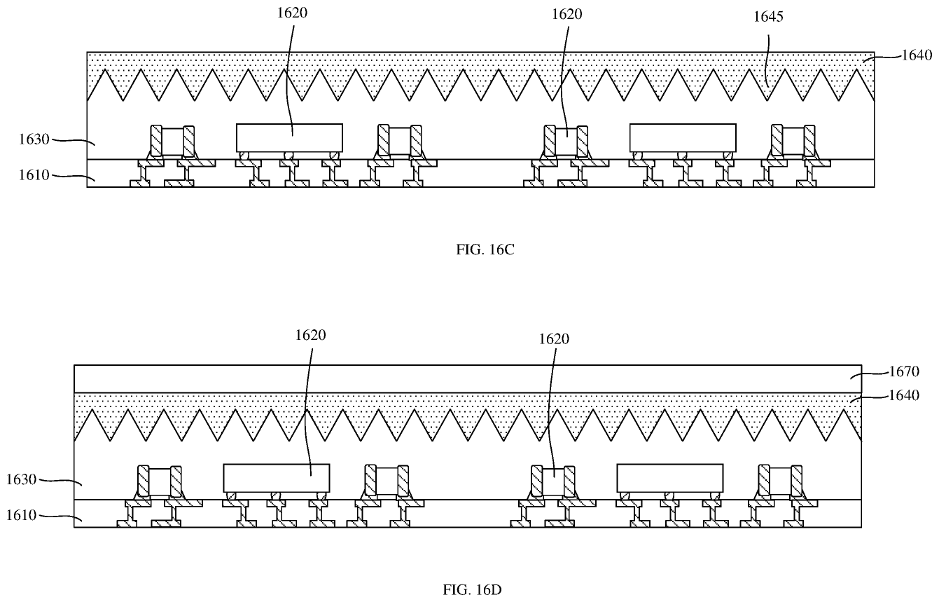

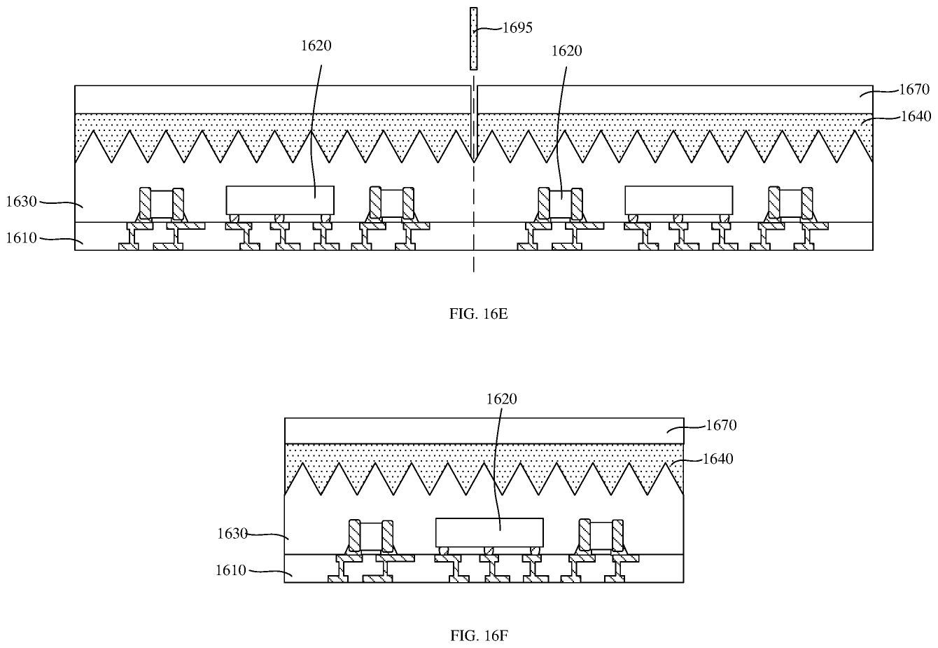

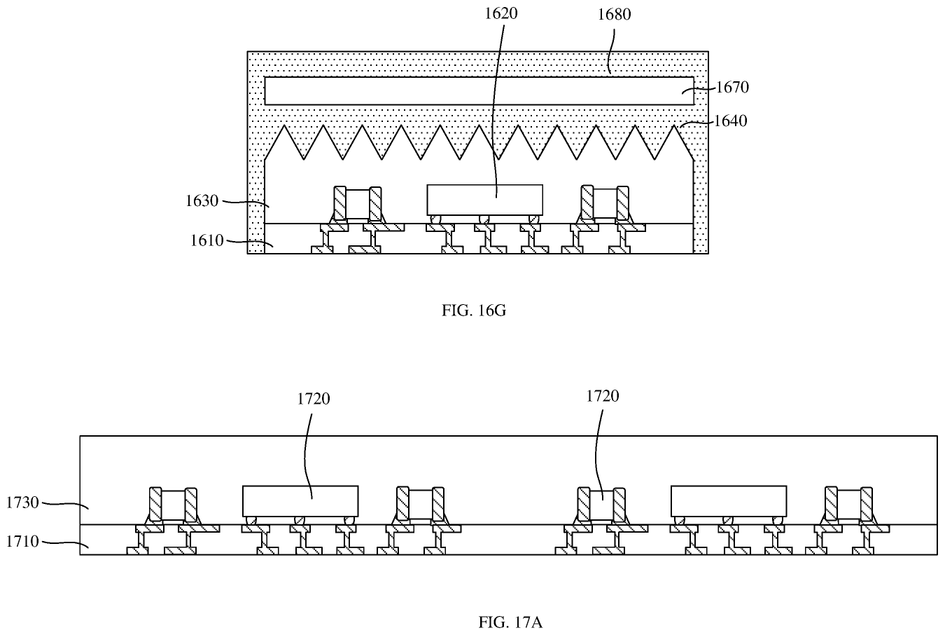

Referring to FIGS. 16A to 16G, various steps of a method for forming a semiconductor device are illustrated according to an embodiment of the present application. For example, the method can also be used to form the semiconductor device 600A shown in FIG. 6A. In the following, the method will be described with reference to FIGS. 16A to 16G in more details.

As shown in FIG. 16A, a package is provided. The package includes a substrate 1610 and a plurality of electronic components 1620. The electronic components 1620 are mounted on the top surface of the substrate 1610. A first encapsulant 1630 is formed on the substrate 1610 and encapsulates the electronic components 1620. For example, a mold with a planar bottom surface may be provided and engaged with the package, and then encapsulation material is injected into the mold to form the first encapsulant 1630 on the substrate 1610 using compressive molding, transfer molding, liquid encapsulant molding, or other suitable process.

Afterwards, as shown in FIG. 16B, the top surface of the first encapsulant 1630 is patterned to form a plurality of encapsulant protrusions 1635. Each encapsulant protrusion 1635 may have one or more inclined sidewalls converging at a pointed tip. In some examples, a laser ablation process may be employed to form the plurality of encapsulant protrusions 1635. In some examples, a chemical texturing process may be employed to form the plurality of encapsulant protrusions 1635.

Afterwards, referring to FIG. 16C, a first EMI shielding layer 1640 is formed on the first encapsulant 1630 using sputtering, spraying, printing, plating, evaporation, CVD, PVD, or other suitable process. The first EMI shielding layer 1640 has a bottom surface conforming to the plurality of encapsulant protrusions 1635 of the first encapsulant 1630, and a planar top surface. That is, a plurality of shield protrusions 1645 of the first EMI shielding layer 1640 may extend downwards into respective recesses formed among the encapsulant protrusions 1635 of the first encapsulant 1630.

As shown in FIG. 16D, a second encapsulant 1670 is formed on the first EMI shielding layer 1640. For example, a mold with a planar bottom surface may be provided and engaged with the package, and then an encapsulation material is injected into the mold to form the second encapsulant 1670. Thus, the second encapsulant 1670 may also has a planar top surface.

Afterwards, the package shown in FIG. 16E is singulated into individual devices as shown in FIG. 16F. For example, as shown in FIG. 16E, the substrate 1610 can be singulated into individual devices at singulation channels using a saw blade 1695. In some other examples, a laser cutting tool can also be used to singulate the substrate 1610.

Afterwards, referring to FIG. 16G, a second EMI shielding layer 1680 is formed on the second encapsulant 1670. The second EMI shielding layer 1680 covers the top and lateral surfaces of the second encapsulant 1670, the lateral surfaces of the first encapsulant 1630, and the lateral surface of the substrate 1610. The second EMI shielding layer 1680 also covers and electrically connects to the exposed lateral surfaces of the first EMI shielding layer 1640. As the second encapsulant 1670 has a planar top surface, the second EMI shielding layer 1680 may also have a planar top surface.

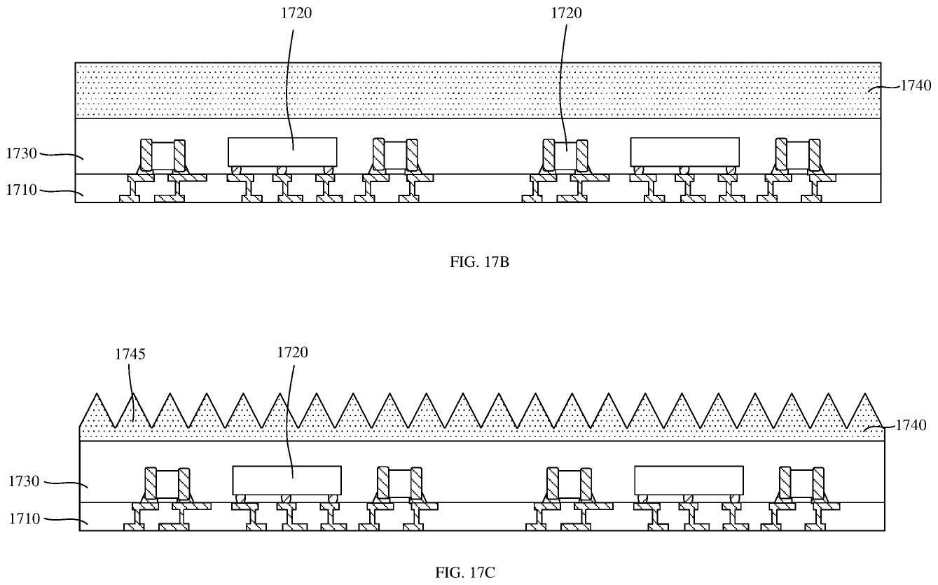

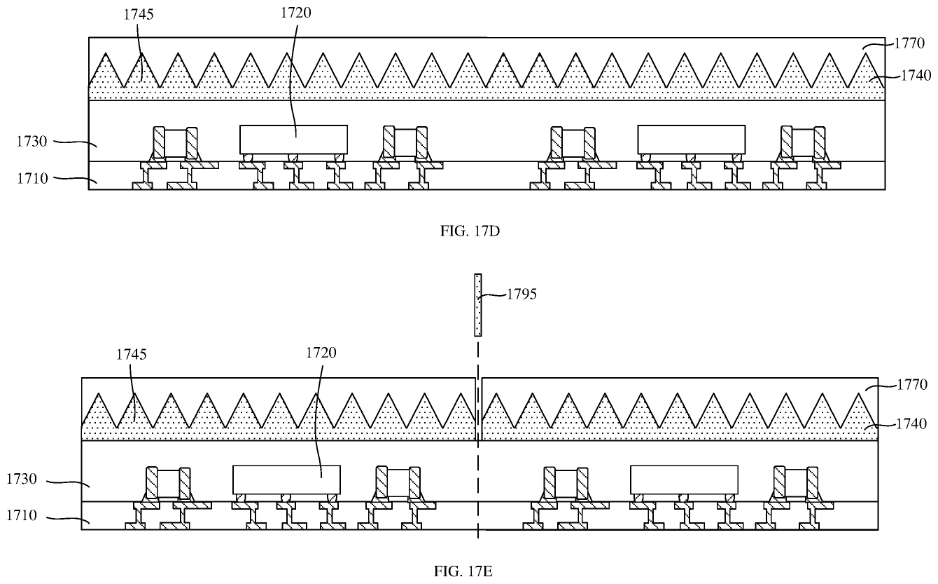

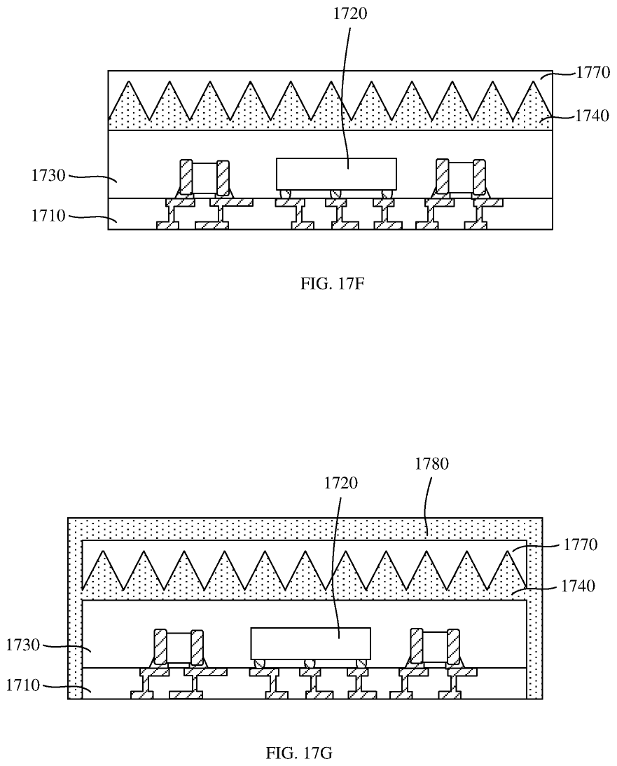

Referring to FIGS. 17A to 17G, various steps of a method for forming a semiconductor device are illustrated according to an embodiment of the present application. For example, the method can also be used to form the semiconductor device 700A shown in FIG. 7A. In the following, the method will be described with reference to FIGS. 17A to 17G in more details.

As shown in FIG. 17A, a package is provided. The package includes a substrate 1710 and a plurality of electronic components 1720. The electronic components 1720 are mounted on the top surface of the substrate 1710. A first encapsulant 1730 is formed on the substrate 1710 and encapsulates the electronic components 1720. For example, a mold with a planar bottom surface may be provided and engaged with the package, and then an encapsulation material is injected into the mold to form the first encapsulant 1730 on the substrate 1710 using compressive molding, transfer molding, liquid encapsulant molding, or other suitable process.

Afterwards, referring to FIG. 17B, a first EMI shielding layer 1740 is formed on the first encapsulant 1730 using sputtering, spraying, printing, plating, evaporation, CVD, PVD, or other suitable process.

Referring to FIG. 17C, the top surface of the first EMI shielding layer 1740 is patterned to form a plurality of shield protrusions 1745. Each shield protrusions 1745 may have one or more inclined sidewalls converging at a pointed tip. In some examples, a laser ablation process may be employed to form the plurality of shield protrusions 1745. In some examples, a chemical texturing process may be employed to form the plurality of shield protrusions 1745.

As shown in FIG. 17D, a second encapsulant 1770 is formed on the first EMI shielding layer 1740. For example, a mold with a planar bottom surface may be provided and engaged with the package, and then an encapsulation material is injected into the mold to form the second encapsulant 1770. Thus, the second encapsulant 1770 may also has a planar top surface.

Afterwards, the package shown in FIG. 17E is singulated into individual devices as shown in FIG. 17F. For example, as shown in FIG. 17E, the substrate 1710 can be singulated into individual devices at singulation channels using a saw blade 1795. In some other examples, a laser cutting tool can also be used to singulate the substrate 1710.

Afterwards, referring to FIG. 17G, a second EMI shielding layer 1780 is formed on the second encapsulant 1770. The second EMI shielding layer 1780 covers the top and lateral surfaces of the second encapsulant 1770, the lateral surfaces of the first encapsulant 1730, and the lateral surface of the substrate 1710. The second EMI shielding layer 1780 also covers and electrically connects to the exposed lateral surfaces of the first EMI shielding layer 1740. As the second encapsulant 1770 has a planar top surface, the second EMI shielding layer 1780 may also have a planar top surface.

It could be understood that the methods described with reference to FIGS. 13A to 13G, FIGS. 14A to 14G, FIGS. 15A to 15G, FIGS. 16A to 16G, and FIGS. 17A to 17G can also be used to form the semiconductor devices 500B, 600B and 700B shown in FIG. 5B, FIG. 6B and FIG. 7B, the semiconductor devices 500C, 600C and 700C shown in FIG. 5C, FIG. 6C and FIG. 7C, and the semiconductor devices 500D, 600D and 700D shown in FIG. 5D, FIG. 6D and FIG. 7D. For example, the steps described with reference to FIGS. 8A-8E and FIGS. 10A-10E can be used to form the second EMI shielding layer of the semiconductor devices 500B, 600B and 700B; the steps described with reference to FIGS. 8A-8D and 9 and FIGS. 10A-10D and 11 can be used to form the second EMI shielding layer of the semiconductor devices 500C, 600C and 700C; and the steps described with reference to FIGS. 12A-12E can be used to form the second EMI shielding layer of the semiconductor devices FIG. 5D, FIG. 6D and FIG. 7D, which will not be repeated.

While the processes for making the semiconductor device are illustrated in conjunction with corresponding figures, it will be understood by those skilled in the art that modifications and adaptations to the process may be made without departing from the scope of the present invention.

The discussion herein included numerous illustrative figures that showed various portions of a semiconductor device and a method of manufacturing thereof. For illustrative clarity, such figures did not show all aspects of each example assembly. Any of the example devices and/or methods provided herein may share any or all characteristics with any or all other devices and/or methods provided herein. It could be understood that, embodiments described in the context of one of the devices or methods are analogously valid for the other devices or methods. Similarly, embodiments described in the context of a device are analogously valid for a method, and vice versa. Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor device, comprising:
a substrate;
an electronic component mounted on the substrate;
a first encapsulant disposed on the substrate and encapsulating the electronic component; and
a first electromagnetic interference (EMI) shielding layer disposed on the first encapsulant, wherein the first EMI shielding layer comprises a first plurality of shield protrusions each having one or more inclined sidewalls.

2. The semiconductor device of claim 1, wherein the one or more inclined sidewalls converge at a pointed tip.

3. The semiconductor device of claim 2, wherein at least one of the first plurality of shield protrusions has a pyramidal shape.

4. The semiconductor device of claim 1, wherein the first encapsulant comprises a first plurality of encapsulant protrusions corresponding to the first plurality of shield protrusions, and the first EMI shielding layer comprises a bottom surface conforming to the first plurality of encapsulant protrusions, and a top surface parallel to the bottom surface.

5. The semiconductor device of claim 1, wherein the first EMI shielding layer comprises a planar top surface and a bottom surface from which the first plurality of shield protrusions protrude, and the first encapsulant comprises a first plurality of recesses for receiving the first plurality of shield protrusions respectively.

6. The semiconductor device of claim 1, wherein the first EMI shielding layer comprises a planar bottom surface disposed on the first encapsulant, and a top surface from which the first plurality of shield protrusions protrude.

7. The semiconductor device of claim 6, further comprising:
a second encapsulant disposed on the first EMI shielding layer; and
a second EMI shielding layer disposed on the second encapsulant and electrically coupled to the first EMI shielding layer.

8. The semiconductor device of claim 7, wherein the second EMI shielding layer has a planar top surface and a planar bottom surface.

9. The semiconductor device of claim 7, wherein the second encapsulant comprises a second plurality of encapsulant protrusions each having one or more inclined sidewalls, and the second EMI shielding layer comprises a bottom surface conforming to the second plurality of encapsulant protrusions, and a top surface parallel to the bottom surface.

10. The semiconductor device of claim 7, wherein the second EMI shielding layer comprises a second plurality of shield protrusions each having one or more inclined sidewalls, the second EMI shielding layer has a planar top surface and a bottom surface from which the second plurality of shield protrusions protrude, and the second encapsulant comprises a second plurality of recesses for receiving the second plurality of shield protrusions respectively.

11. The semiconductor device of claim 7, wherein the second EMI shielding layer comprises a second plurality of shield protrusions each having one or more inclined sidewalls, the second EMI shielding layer has a planar bottom surface disposed on the second encapsulant, and a top surface from which the second plurality of shield protrusions protrude.

12. A method for making a semiconductor device, comprising:
providing a package comprising:
a substrate; and
an electronic component mounted on the substrate;
forming a first encapsulant on the substrate and encapsulating the electronic component; and
forming a first electromagnetic interference (EMI) shielding layer on the first encapsulant, wherein the first EMI shielding layer comprising a first plurality of shield protrusions each having one or more inclined sidewalls.

13. The method device of claim 12, wherein the one or more inclined sidewalls converge at a pointed tip.

14. The method of claim 12, wherein forming the first encapsulant on the substrate comprises:
providing a mold, wherein the mold comprises a plurality of recesses exposed from a bottom surface of the mold;
engaging the mold and the package; and
injecting encapsulation material into the mold to form the first encapsulant on the substrate, wherein the first encapsulant comprises a plurality of encapsulant protrusions formed in the plurality of recesses of the mold.

15. The method of claim 12, wherein forming the first encapsulant on the substrate comprises:
providing a mold having a planar bottom surface;
engaging the mold and the package;
injecting encapsulation material into the mold to form the first encapsulant on the substrate, wherein the first encapsulant comprises a planar top surface; and
patterning the top surface of the first encapsulant to form a plurality of encapsulant protrusions.

16. The method of claim 15, wherein the first EMI shielding layer comprises a bottom surface conforming to the plurality of encapsulant protrusions, and a top surface parallel to the bottom surface.

17. The method of claim 15, wherein the first EMI shielding layer has a planar top surface and a bottom surface from which the first plurality of shield protrusions protrude, and the first plurality of shield protrusions are received by recesses formed among the plurality of encapsulant protrusions of the first encapsulant.

18. The method of claim 12, wherein the first encapsulant comprise a planar top surface, and forming the first EMI shielding layer on the first encapsulant comprises:
depositing the first EMI shielding layer on the first encapsulant; and
patterning a top surface of the first EMI shielding layer to form the first plurality of shield protrusions.

19. The method of claim 12, further comprising:
forming a second encapsulant on the first EMI shielding layer; and
forming a second EMI shielding layer on the second encapsulant and electrically coupled to the first EMI shielding layer.

20. The method of claim 19, wherein the second EMI shielding layer comprising a second plurality of shield protrusions each having one or more inclined sidewalls.
